(19) United States
(12) Patent Application Publication
(10) Pub. No.: US 2018/0331697 A1
(43) Pub. Date: Nov. 15, 2018

(54) NOMINAL COMPLEXITY AND WEIGHTED COMBINATIONS FOR POLAR CODE CONSTRUCTION

(71) Applicant: QUALCOMM Incorporated, San Diego, CA (US)

(72) Inventors: Jamie Menjay Lin, San Diego, CA (US); Yang Yang, San Diego, CA (US); Gabi Sarkis, San Diego, CA (US)

(21) Appl. No.: 15/976,439

(22) Filed: May 10, 2018

Related U.S. Application Data
(60) Provisional application No. 62/506,305, filed on May 15, 2017.

(51) Int. Cl. H03M 13/11; H03M 13/13; H03M 13/37

(52) U.S. Cl. CPC H03M 13/1148; H04W 4/70; H03M 13/37; H03M 13/13

(57) ABSTRACT

Methods, systems, and devices for wireless communication are described. A wireless device may decode a polar coded codeword using a successive cancelation (SC) or successive cancelation list (SCL) decoder. The construction of the codeword may be based on multiple factors, such as a decoding complexity, reliability, codeword size, number of information bits, type of communication, etc. In some cases, multiple codeword constructions may be compared (e.g., with various weights applied to the relevant factors) and an optimal construction selected. Techniques described herein are applicable both to the selection of an optimal codeword as well as decoding operations. Specifically, the described techniques may allow for a reduced decoding complexity through the use of subtree pruning, in which characteristics of the polar scheme (e.g., the scheme selected by the encoder) may be exploited to reduce the complexity of the decoding operation.

### CROSS REFERENCES

The present Application for Patent claims the benefit of U.S. Provisional Patent Application No. 62/506,305 by LIN, et al., entitled “NOMINAL COMPLEXITY AND WEIGHTED COMBINATIONS FOR POLAR CODE CONSTRUCTION,” filed May 15, 2017, which is assigned to the assignee hereof, and expressly incorporated by reference herein.

### BACKGROUND

The following relates generally to wireless communication, and more specifically to nominal complexity and weighted combinations for polar code construction.

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system). A wireless multiple-access communications system may include a number of base stations or access network nodes, each simultaneously supporting communication for multiple communication devices, which may be otherwise known as user equipment (UE).

Information transmitted between devices in wireless multiple-access communications systems may be encoded into a codeword in order to improve the reliability of successfully decoding the transmitted information. In some cases, codewords may provide redundancy, which may be used to correct errors that result from the transmission environment (e.g., path loss, obstacles, etc.). Some examples of encoding algorithms with error correcting codes include convolutional codes (CCs), low-density parity-check (LDPC) codes, and polar codes. A polar code is an example of a linear block error correcting code and has been shown to asymptotically approach the theoretical channel capacity as the code length increases. Polar codes are based on polarization of sub-channels used for information bits or frozen bits (e.g., predetermined bits set to a ‘0’ or a ‘1’), with information bits generally assigned to the higher reliability sub-channels. However, practical implementations of a polar decoder are complex due to the ordered nature of decoding and list decoding techniques used for improving the error-correcting performance. Techniques for high-performance polar codes that reduce complexity of decoding are desired.

### SUMMARY

The described techniques relate to improved methods, systems, devices, or apparatuses that support nominal complexity and weighted combinations for polar code construction. Generally, the described techniques provide for receiving and transmitting a codeword encoded using a polar code. The codeword contains a plurality of information bits as well as one or more frozen bits. The information bits may be allocated to a given set of polar channel indices. The set of polar channel indices may be determined based at least in part on a reliability metric of each index of the set and a decoding complexity associated with the codeword as a whole. Accordingly, receiving and transmitting devices may be configured to identify (e.g., may dynamically determine, may identify based on some pre-configured information, etc.) the set of polar channel indices for a given situation (e.g., a given codeword size, a number of information bits, a type of communication, etc.).

A method of wireless communication is described. The method may include receiving a codeword encoded using a polar code, the codeword generated based on a set of information bits, identifying a set of polar bit channel indices corresponding to the set of information bits, where the set of polar bit channel indices is selected from a set of polar bit channel indices of the polar code based on a reliability metric and a decoding complexity metric associated with the set of polar bit channel indices, and decoding the codeword to obtain the set of information bits based on the set of polar bit channel indices.

An apparatus for wireless communication is described. The apparatus may include a processor, memory in electronic communication with the processor, and instructions stored in the memory. The instructions may be executable by the processor to cause the apparatus to receive a codeword encoded using a polar code, the codeword generated based on a set of information bits, identify a set of polar bit channel indices corresponding to the set of information bits, where the set of polar bit channel indices is selected from a set of polar bit channel indices of the polar code based on a reliability metric and a decoding complexity metric associated with the set of polar bit channel indices, and decode the codeword to obtain the set of information bits based on the set of polar bit channel indices.

Another apparatus for wireless communication is described. The apparatus may include means for receiving a codeword encoded using a polar code, the codeword generated based on a set of information bits, identifying a set of polar bit channel indices corresponding to the set of information bits, where the set of polar bit channel indices is selected from a set of polar bit channel indices of the polar code based on a reliability metric and a decoding complexity metric associated with the set of polar bit channel indices, and decoding the codeword to obtain the set of information bits based on the set of polar bit channel indices.

A non-transitory computer-readable medium storing code for wireless communication is described. The code may include instructions executable by a processor to receive a codeword encoded using a polar code, the codeword generated based on a set of information bits, identify a set of polar bit channel indices corresponding to the set of information bits, where the set of polar bit channel indices is selected from a set of polar bit channel indices of the polar code based on a reliability metric and a decoding complexity metric associated with the set of polar bit channel indices, and decode the codeword to obtain the set of information bits based on the set of polar bit channel indices.

In some examples of the method, apparatuses, and non-transitory computer-readable medium described herein, the decoding complexity metric may be based on a number of logarithmic likelihood ratio (LLR) derivations for at least one polar bit channel index of the set of polar bit channel indices, a number of bit feedback operations for the at least one polar bit channel index of the set of polar bit channel indices, or a combination thereof.

In some examples of the method, apparatuses, and non-transitory computer-readable medium described herein, for the at least one polar bit channel index of the set of polar bit channel indices, one or both of the number of bit feedback operations or the number of LLR derivations may be based on a tree traversal depth between the at least one polar bit channel index and a prior polar bit channel index of the set of polar bit channel indices.

In some examples of the method, apparatuses, and non-transitory computer-readable medium described herein, the decoding complexity metric may be determined based on merging single parity check decoding operations and repetition decoding operations for a subtree of the polar code.

In some examples of the method, apparatuses, and non-transitory computer-readable medium described herein, the subtree includes less than two of the set of polar bit channel indices and at least one frozen bit index.

In some examples of the method, apparatuses, and non-transitory computer-readable medium described herein, the decoding complexity metric may be generated based on a tree traversal depth between adjacent polar bit channel indices of the set of polar bit channel indices, the subtree including one of the adjacent polar bit channel indices.

In some examples of the method, apparatuses, and non-transitory computer-readable medium described herein, the identifying the set of polar bit channel indices may include operations, features, means, or instructions for determining a provisional set of polar bit channel indices for the set of information bits based on a reliability metric for the provisional set of polar bit channel indices, determining an aggregate performance metric for the provisional set of polar bit channel indices, the aggregate performance metric based on a provisional decoding complexity metric, iteratively modifying at least one index of the provisional set of polar bit channel indices and determining a modified aggregate performance metric for each of a set of search branches and adopting the modified provisional set of polar bit channel indices having a highest modified aggregate performance metric as the set of polar bit channel indices.

Some examples of the method, apparatuses, and non-transitory computer-readable medium described herein may further include operations, features, means, or instructions for determining a weighted combination of the reliability metric and the decoding complexity metric by applying a first weighting factor to the reliability metric and applying a second weighting factor to the decoding complexity metric, where the set of polar bit channel indices may be selected from the set of polar bit channel indices of the polar code based on the weighted combination.

In some examples of the method, apparatuses, and non-transitory computer-readable medium described herein, one or both of the first weighting factor or the second weighting factor may be based on a type of wireless communication protocol associated with the codeword.

In some examples of the method, apparatuses, and non-transitory computer-readable medium described herein, the type of wireless communication protocol includes one of enhanced mobile broadband (eMBB), ultra-reliable low latency communication (URLLC), Internet of Things (IoT) communication, or machine-type communication (MTC).

In some examples of the method, apparatuses, and non-transitory computer-readable medium described herein, an aggregate reliability weight for eMBB may be greater than an aggregate reliability weight for URLLC and MTC, where the aggregate reliability weights may be determined based on the first weighting factor applied to the reliability metric.

In some examples of the method, apparatuses, and non-transitory computer-readable medium described herein, an aggregate complexity weight for eMBB may be less than an aggregate complexity weight for URLLC and MTC, where the aggregate complexity weights may be determined based on the second weighting factor applied to the decoding complexity metric.

A method of wireless communication is described. The method may include identifying a set of polar bit channel indices corresponding to a set of information bits of an information bit vector for encoding using a polar code, where the set of polar bit channel indices is selected from a set of polar bit channel indices of the polar code based on a reliability metric and a decoding complexity metric associated with the set of polar bit channel indices, encoding the set of information bits according to the polar code based on the set of polar bit channel indices to obtain a codeword, and transmitting the codeword.

An apparatus for wireless communication is described. The apparatus may include a processor, memory in electronic communication with the processor, and instructions stored in the memory. The instructions may be executable by the processor to cause the apparatus to identify a set of polar bit channel indices corresponding to a set of information bits of an information bit vector for encoding using a polar code, where the set of polar bit channel indices is selected from a set of polar bit channel indices of the polar code based on a reliability metric and a decoding complexity metric associated with the set of polar bit channel indices, encode the set of information bits according to the polar code based on the set of polar bit channel indices to obtain a codeword, and transmit the codeword.

Another apparatus for wireless communication is described. The apparatus may include means for identifying a set of polar bit channel indices corresponding to a set of information bits of an information bit vector for encoding using a polar code, where the set of polar bit channel indices is selected from a set of polar bit channel indices of the polar code based on a reliability metric and a decoding complexity metric associated with the set of polar bit channel indices, encoding the set of information bits according to the polar code based on the set of polar bit channel indices to obtain a codeword, and transmitting the codeword.

A non-transitory computer-readable medium storing code for wireless communication is described. The code may include instructions executable by a processor to identify a set of polar bit channel indices corresponding to a set of information bits of an information bit vector for encoding using a polar code, where the set of polar bit channel indices is selected from a set of polar bit channel indices of the polar code based on a reliability metric and a decoding complexity metric associated with the set of polar bit channel indices, encode the set of information bits according to the polar code based on the set of polar bit channel indices to obtain a codeword, and transmit the codeword.

In some examples of the method, apparatuses, and non-transitory computer-readable medium described herein, the decoding complexity metric may be based on a number of LLR derivations for at least one polar bit channel index of the set of polar bit channel indices, a number of bit feedback operations for the at least one polar bit channel index of the set of polar bit channel indices, or a combination thereof.

In some examples of the method, apparatuses, and non-transitory computer-readable medium described herein, for the at least one polar bit channel index of the set of polar bit channel indices, one or both of the number of bit feedback operations or the number of LLR derivations may be based on a tree traversal depth between the at least one polar bit channel index and a prior polar bit channel index of the set of polar bit channel indices.

In some examples of the method, apparatuses, and non-transitory computer-readable medium described herein, the decoding complexity metric may be determined based on merging single parity check decoding operations and repetition decoding operations for a subtree of the polar code.

In some examples of the method, apparatuses, and non-transitory computer-readable medium described herein, the subtree includes less than two of the set of polar bit channel indices and at least one frozen bit index.

In some examples of the method, apparatuses, and non-transitory computer-readable medium described herein, the decoding complexity metric may be generated based on a tree traversal depth between adjacent polar bit channel indices of the set of polar bit channel indices, the subtree including one of the adjacent polar bit channel indices.

In some examples of the method, apparatuses, and non-transitory computer-readable medium described herein, the identifying the set of polar bit channel indices may include operations, features, means, or instructions for determining a provisional set of polar bit channel indices for the set of information bits based on a reliability metric for the provisional set of polar bit channel indices, determining an aggregate performance metric for the provisional set of polar bit channel indices, the aggregate performance metric based on a provisional decoding complexity metric, iteratively modifying at least one index of the provisional set of polar bit channel indices and determining a modified aggregate performance metric for each of a set of search branches and adopting the modified provisional set of polar bit channel indices having a highest modified aggregate performance metric as the set of polar bit channel indices.

Some examples of the method, apparatuses, and non-transitory computer-readable medium described herein may further include operations, features, means, or instructions for determining a weighted combination of the reliability metric and the decoding complexity metric by applying a first weighting factor to the reliability metric and applying a second weighting factor to the decoding complexity metric, where the set of polar bit channel indices may be selected from the set of polar bit channel indices of the polar code based on the weighted combination.

In some examples of the method, apparatuses, and non-transitory computer-readable medium described herein, one or both of the first weighting factor or the second weighting factor may be based on a type of wireless communication protocol associated with the codeword.

In some examples of the method, apparatuses, and non-transitory computer-readable medium described herein, the type of wireless communication protocol includes one of eMBB, URLLC, IoT communication, or MTC.

In some examples of the method, apparatuses, and non-transitory computer-readable medium described herein, an aggregate reliability weight for eMBB may be greater than an aggregate reliability weight for URLLC and MTC, where the aggregate reliability weights may be determined based on the first weighting factor applied to the reliability metric.

In some examples of the method, apparatuses, and non-transitory computer-readable medium described herein, an aggregate complexity weight for eMBB may be less than an aggregate complexity weight for URLLC and MTC, where the aggregate complexity weights may be determined based on the second weighting factor applied to the decoding complexity metric.

### BRIEF DESCRIPTION OF THE DRAWINGS

FIG. 1 illustrates an example of a system for wireless communication that supports nominal complexity and weighted combinations for polar code construction in accordance with aspects of the present disclosure.

FIG. 2 illustrates an example of a device that supports nominal complexity and weighted combinations for polar code construction in accordance with aspects of the present disclosure.

FIG. 3 illustrates an example of a polar code structure that supports nominal complexity and weighted combinations for polar code construction in accordance with aspects of the present disclosure.

FIG. 4 illustrates an example of a polar code subtree that supports nominal complexity and weighted combinations for polar code construction in accordance with aspects of the present disclosure.

FIGS. 5A and 5B illustrate example coder/decoder segments that support nominal complexity and weighted combinations for polar code construction in accordance with aspects of the present disclosure.

FIGS. 6 through 8 illustrate example polar code trees that supports nominal complexity and weighted combinations for polar code construction in accordance with aspects of the present disclosure.

FIG. 9 illustrates an example process flow that supports nominal complexity and weighted combinations for polar code construction in accordance with aspects of the present disclosure.

FIGS. 10 through 12 show block diagrams of a device that supports nominal complexity and weighted combinations for polar code construction in accordance with aspects of the present disclosure.

FIG. 13 illustrates a block diagram of a system including a wireless device that supports nominal complexity and weighted combinations for polar code construction in accordance with aspects of the present disclosure.

FIGS. 14 through 16 illustrate methods for nominal complexity and weighted combinations for polar code construction in accordance with aspects of the present disclosure.

### DETAILED DESCRIPTION

Some wireless communications systems may support the use of polar codes, which are a type of linear block error correcting code that has been shown to approach the theoretical channel capacity as the code length increases. The number of sub-channels for polar codes follows a power function (e.g., 2^{X}), where a number of information bits are mapped to different polarized sub-channels (e.g., polar channel indices). The capacity of a given polar channel index may be a function of a reliability metric of the polar channel index. Information bits may be loaded on a set of polar channel indices, and the remaining bits (e.g., frozen bits) may be loaded on the remaining polarized bit channels. The number of permutations for the set of polar channel indices for a given polar code length may be large. As an example, a codeword may be encoded using a polar code of length 256, of which 16 polar channel indices are allocated as information bits. In such a scenario, the number of potential information bit polar index sets (i.e., the number of groups of 16 indices in which at least one index differs between each set) is on the order of 10³⁸.

Error correction performance of the polar code may be optimized with selection of the information bit polar index set based on reliability of the polar indices. However, polar codes that are constructed purely based on the reliability of successfully receiving and decoding a codeword may not provide sufficient performance in all scenarios. For example, devices with constrained battery power and/or devices for whom low latency is a key performance indicator may in some cases prefer selection of the information bit polar index set to reduce decoding complexity (e.g., at the cost of lower reliability). However, when considering that devices may support multiple schemes in which the codeword length and/or the number of information bits vary between schemes, and further considering that different decoders may implement decoding functions using different schemes (e.g., a software decoder, a hardware decoder) with different complexity constraints, comparison of decoding performance and decoding complexity between different sets of indices becomes computationally rigorous.

The described techniques are directed to optimizing the decoding performance and decoding complexity for polar codes. In some cases, determination of the information bit polar index set may be based on one or more factors (e.g., reliability, decoding complexity, number of feedback operations, etc.) that are appropriately weighted in order to produce an aggregate metric for the information bit polar index set (e.g., which can be compared to aggregate metrics for other information bit polar index sets). In some cases, determination of a decoding complexity for a given information bit polar index set may be based at least in part on simplifications of the decoding operation in accordance with various techniques described herein. Additionally or alternatively, the described simplifications may be used in practice at a decoder in order to reduce the decoding complexity. The simplifications are generally based on sub-tree pruning of a polar code tree (e.g., in which given sub-trees within the polar code tree are treated as a block). Strategically grouping calculations into blocks may reduce the number of operations that need to be performed, which may in turn benefit the decoding device (e.g., in terms of latency, power consumption, etc.).

Aspects of the disclosure are initially described in the context of a wireless communications system. Aspects of the disclosure are then illustrated by and described with reference to various polar code structures, subtrees, and decoding schemes. Aspects of the disclosure are further illustrated by and described with reference to apparatus diagrams, system diagrams, and flowcharts that relate to nominal complexity and weighted combinations for polar code construction.

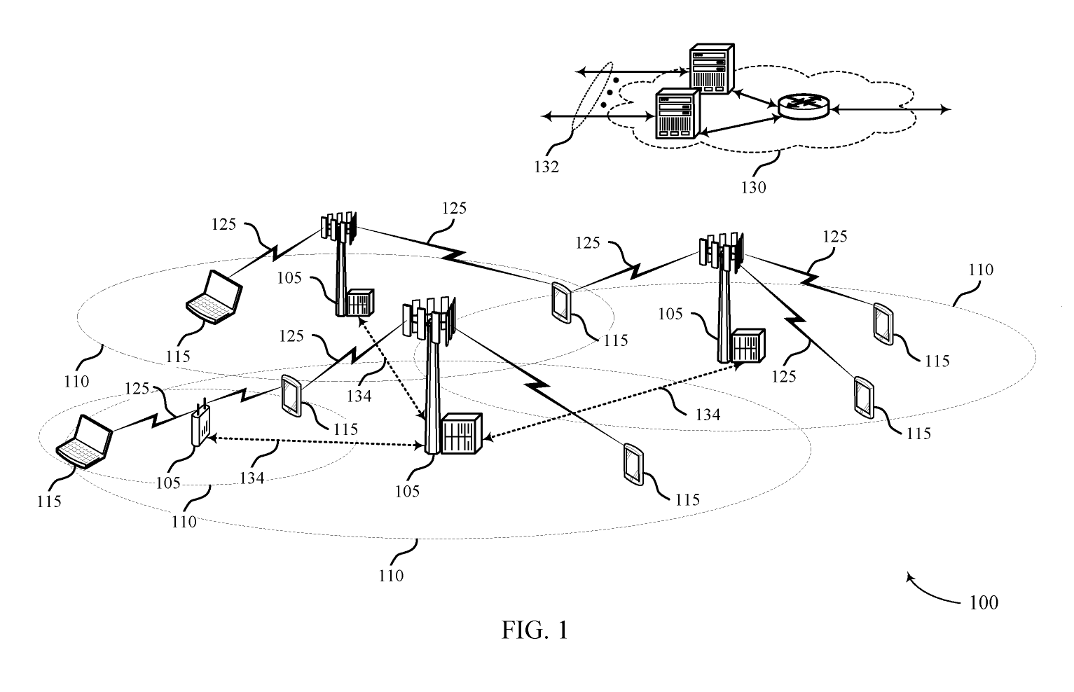

FIG. 1 illustrates an example of a wireless communications system 100 in accordance with various aspects of the present disclosure. The wireless communications system 100 includes base stations 105, UEs 115, and a core network 130. In some examples, the wireless communications system 100 may be a Long Term Evolution (LTE), LTE-Advanced (LTE-A) network, or a New Radio (NR) network. In some cases, wireless communications system 100 may support enhanced broadband communications, ultra-reliable (i.e., mission critical) communications, low latency communications, and communications with low-cost and low-complexity devices. Base stations 105 and UEs 115 may use a polar code design to encode information bits of an input vector to obtain a codeword for transmission. In some cases, the base stations 105 and UEs 115 may reduce decoding complexity (e.g., at the expense of decoding reliability) for these transmissions by shifting a position of at least one information bit. Additionally or alternatively, a decoder may achieve reductions in decoding complexity and/or latency using one or more simplification techniques described below.

Base stations 105 may wirelessly communicate with UEs 115 via one or more base station antennas. In some cases, the transmissions may be encoded using a polar code design. Each base station 105 may provide communication coverage for a respective geographic coverage area 110. Communication links 125 shown in wireless communications system 100 may include uplink transmissions from a UE 115 to a base station 105, or downlink transmissions from a base station 105 to a UE 115. Control information and data may be multiplexed on an uplink channel or downlink according to various techniques. Control information and data may be multiplexed on a downlink channel, for example, using time division multiplexing (TDM) techniques, frequency division multiplexing (FDM) techniques, or hybrid TDM-FDM techniques. In some examples, the control information transmitted during a transmission time interval (TTI) of a downlink channel may be distributed between different control regions in a cascaded manner (e.g., between a common control region and one or more UE-specific control regions).

UEs 115 may be dispersed throughout the wireless communications system 100, and each UE 115 may be stationary or mobile. A UE 115 may also be referred to as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. A UE 115 may also be a cellular phone, a personal digital assistant (PDA), a wireless modem, a wireless communication device, a handheld device, a tablet computer, a laptop computer, a cordless phone, a personal electronic device, a handheld device, a personal computer, a wireless local loop (WLL) station, an Internet of Things (IoT) device, an Internet of Everything (IoE) device, a machine type communication (MTC) device, an appliance, an automobile, or the like.

In some cases, a UE 115 may also be able to communicate directly with other UEs (e.g., using a peer-to-peer (P2P) or device-to-device (D2D) protocol). One or more of a group of UEs 115 utilizing D2D communications may be within the coverage area 110 of a cell. Other UEs 115 in such a group may be outside the coverage area 110 of a cell, or otherwise unable to receive transmissions from a base station 105. In some cases, groups of UEs 115 communicating via D2D communications may utilize a one-to-many (1:M) system in which each UE 115 transmits to every other UE 115 in the group. In some cases, a base station 105 facilitates the scheduling of resources for D2D communications. In other cases, D2D communications are carried out independent of a base station 105.

Some UEs 115, such as MTC or IoT devices, may be low cost or low complexity devices, and may provide for automated communication between machines, i.e., Machine-to-Machine (M2M) communication. M2M or MTC may refer to data communication technologies that allow devices to communicate with one another or a base station without human intervention. For example, M2M or MTC may refer to communications from devices that integrate sensors or meters to measure or capture information and relay that information to a central server or application program that can make use of the information or present the information to humans interacting with the program or application. Some UEs 115 may be designed to collect information or enable automated behavior of machines. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging.

In some cases, an MTC device may operate using half-duplex (one-way) communications at a reduced peak rate. MTC devices may also be configured to enter a power saving “deep sleep” mode when not engaging in active communications. In some cases, MTC or IoT devices may be designed to support mission critical functions and wireless communications system may be configured to provide ultra-reliable communications for these functions.

Base stations 105 may communicate with the core network 130 and with one another. For example, base stations 105 may interface with the core network 130 through backhaul links 132 (e.g., S1, etc.). Base stations 105 may communicate with one another over backhaul links 134 (e.g., X2, etc.) either directly or indirectly (e.g., through core network 130). Base stations 105 may perform radio configuration and scheduling for communication with UEs 115, or may operate under the control of a base station controller (not shown). In some examples, base stations 105 may be macro cells, small cells, hot spots, or the like. Base stations 105 may also be referred to as evolved NodeBs (eNBs) 105 or next generation NodeBs (gNBs) 105.

A base station 105 may be connected by an S1 interface to the core network 130. The core network may be an evolved packet core (EPC), which may include at least one mobility management entity (MME), at least one serving gateway (S-GW), and at least one Packet Data Network (PDN) gateway (P-GW). The MME may be the control node that processes the signaling between the UE 115 and the EPC. All user Internet Protocol (IP) packets may be transferred through the S-GW, which itself may be connected to the P-GW. The P-GW may provide IP address allocation as well as other functions. The P-GW may be connected to the network operators IP services. The operators IP services may include the Internet, the Intranet, an IP Multimedia Subsystem (IMS), and a Packet-Switched (PS) Streaming Service.

The core network 130 may provide user authentication, access authorization, tracking, Internet Protocol (IP) connectivity, and other access, routing, or mobility functions. At least some of the network devices, such as base station 105 may include subcomponents such as an access network entity, which may be an example of an access node controller (ANC). Each access network entity may communicate with a number of UEs 115 through a number of other access network transmission entities, each of which may be an example of a smart radio head, or a transmission/reception point (TRP). In some configurations, various functions of each access network entity or base station 105 may be distributed across various network devices (e.g., radio heads and access network controllers) or consolidated into a single network device (e.g., a base station 105).

Wireless communications system 100 may operate in an ultra-high frequency (UHF) frequency region using frequency bands from 700 MHz to 2600 MHz (2.6 GHz), although some networks (e.g., a wireless local area network (WLAN)) may use frequencies as high as 4 GHz. This region may also be known as the decimeter band, since the wavelengths range from approximately one decimeter to one meter in length. UHF waves may propagate mainly by line of sight, and may be blocked by buildings and environmental features. However, the waves may penetrate walls sufficiently to provide service to UEs 115 located indoors. Transmission of UHF waves is characterized by smaller antennas and shorter range (e.g., less than 100 km) compared to transmission using the smaller frequencies (and longer waves) of the high frequency (HF) or very high frequency (VHF) portion of the spectrum. In some cases, wireless communications system 100 may also utilize extremely high frequency (EHF) portions of the spectrum (e.g., from 30 GHz to 300 GHz). This region may also be known as the millimeter band, since the wavelengths range from approximately one millimeter to one centimeter in length. Thus, EHF antennas may be even smaller and more closely spaced than UHF antennas. In some cases, this may facilitate use of antenna arrays within a UE 115 (e.g., for directional beamforming). However, EHF transmissions may be subject to even greater atmospheric attenuation and shorter range than UHF transmissions.

Thus, wireless communications system 100 may support millimeter wave (mmW) communications between UEs 115 and base stations 105. Devices operating in mmW or EHF bands may have multiple antennas to allow beamforming. That is, a base station 105 may use multiple antennas or antenna arrays to conduct beamforming operations for directional communications with a UE 115. Beamforming (which may also be referred to as spatial filtering or directional transmission) is a signal processing technique that may be used at a transmitter (e.g., a base station 105) to shape and/or steer an overall antenna beam in the direction of a target receiver (e.g., a UE 115). This may be achieved by combining elements in an antenna array in such a way that transmitted signals at particular angles experience constructive interference while others experience destructive interference.

Multiple-input multiple-output (MIMO) wireless systems use a transmission scheme between a transmitter (e.g., a base station 105) and a receiver (e.g., a UE 115), where both transmitter and receiver are equipped with multiple antennas. Some portions of wireless communications system 100 may use beamforming. For example, base station 105 may have an antenna array with a number of rows and columns of antenna ports that the base station 105 may use for beamforming in its communication with UE 115. Signals may be transmitted multiple times in different directions (e.g., each transmission may be beamformed differently). A mmW receiver (e.g., a UE 115) may try multiple beams (e.g., antenna subarrays) while receiving the synchronization signals.

In some cases, the antennas of a base station 105 or UE 115 may be located within one or more antenna arrays, which may support beamforming or MIMO operation. One or more base station antennas or antenna arrays may be collocated at an antenna assembly, such as an antenna tower. In some cases, antennas or antenna arrays associated with a base station 105 may be located in diverse geographic locations. A base station 105 may multiple use antennas or antenna arrays to conduct beamforming operations for directional communications with a UE 115.

In some cases, wireless communications system 100 may be a packet-based network that operate according to a layered protocol stack. In the user plane, communications at the bearer or Packet Data Convergence Protocol (PDCP) layer may be IP-based. A Radio Link Control (RLC) layer may in some cases perform packet segmentation and reassembly to communicate over logical channels. A Medium Access Control (MAC) layer may perform priority handling and multiplexing of logical channels into transport channels. The MAC layer may also use Hybrid Automatic Repeat Request (HARM) to provide retransmission at the MAC layer to improve link efficiency. In the control plane, the Radio Resource Control (RRC) protocol layer may provide establishment, configuration, and maintenance of an RRC connection between a UE 115 and a network device such as a base station 105, or core network 130 supporting radio bearers for user plane data. At the Physical (PHY) layer, transport channels may be mapped to physical channels.

A shared radio frequency spectrum band may be utilized in an NR shared spectrum system. For example, an NR shared spectrum may utilize any combination of licensed, shared, and unlicensed spectrums, among others. The flexibility of eCC symbol duration and subcarrier spacing may allow for the use of eCC across multiple spectrums. In some examples, NR shared spectrum may increase spectrum utilization and spectral efficiency, specifically through dynamic vertical (e.g., across frequency) and horizontal (e.g., across time) sharing of resources.

In some cases, wireless communications system 100 may utilize both licensed and unlicensed radio frequency spectrum bands. For example, wireless communications system 100 may employ LTE License Assisted Access (LTE-LAA) or LTE Unlicensed (LTE U) radio access technology or NR technology in an unlicensed band such as the 5 Ghz Industrial, Scientific, and Medical (ISM) band. When operating in unlicensed radio frequency spectrum bands, wireless devices such as base stations 105 and UEs 115 may employ listen-before-talk (LBT) procedures to ensure the channel is clear before transmitting data. In some cases, operations in unlicensed bands may be based on a CA configuration in conjunction with CCs operating in a licensed band. Operations in unlicensed spectrum may include downlink transmissions, uplink transmissions, or both. Duplexing in unlicensed spectrum may be based on frequency division duplexing (FDD), time division duplexing (TDD) or a combination of both.

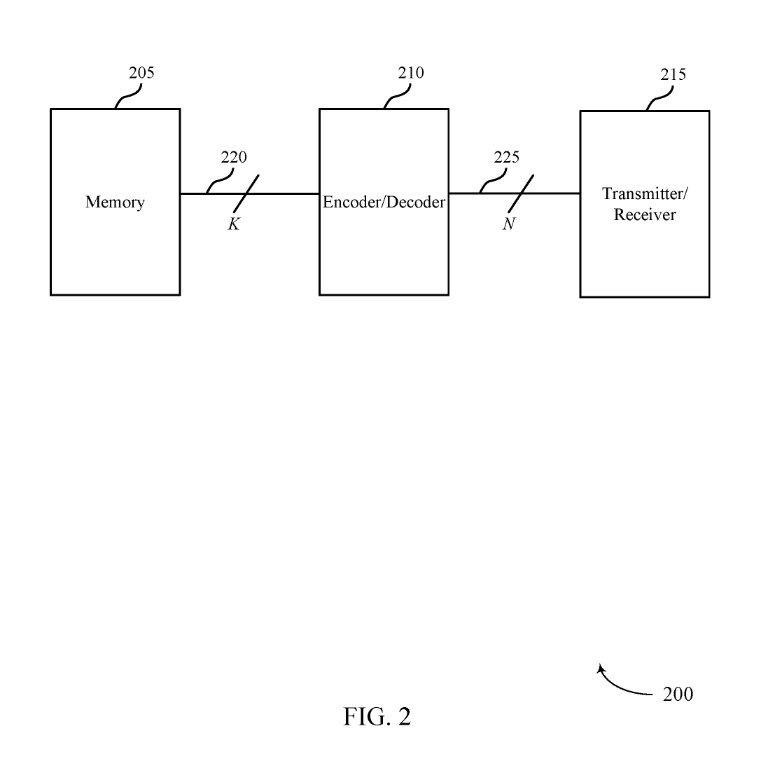

FIG. 2 illustrates an example of a device 200 that supports nominal complexity and weighted combinations for polar code construction in accordance with various aspects of the present disclosure. The device 200 may be any device within a wireless communications system 100 that performs an encoding or decoding process. For example, the device 200 may be a UE 115 or base station 105, as described in FIG. 1.

As shown, device 200 includes a memory 205, an encoder/decoder 210, and a transmitter/receiver 215. Bus 220 may connect memory 205 to encoder/decoder 210 and bus 225 may connect encoder/decoder 210 to transmitter/receiver 215. In some instances, device 200 may have data stored in memory 205 to be transmitted to another device, such as a UE 115 or base station 105. To initiate the transmission process, the device 200 may retrieve from memory 205 data (e.g., in the form of an input vector) for transmission. The data may include a number of information bits provided from memory 205 to encoder/decoder 210 via bus 220. The number of information bits may be represented as a value ‘k,’ as shown. The encoder/decoder 210 may encode the number of information bits and output a codeword having a length ‘N.’ The bits that are not allocated as information bits (i.e., N−k bits) may be assigned as frozen bits. Frozen bits may be bits of a value (e.g., 0) known to both the encoder and decoder (i.e., the encoder encoding information bits at a transmitter and the decoder decoding the codeword received at a receiver). Further, from the receiving device perspective, device 200 may receive encoded data via receiver 215, and decode the encoded data using decoder 210 to obtain the transmitted data.

In some wireless systems, the decoder 210 may be an example of a successive cancellation list (SCL) decoder. A UE 115 or base station 105 may receive a transmission including a codeword at the receiver 215, and may decode the codeword (e.g., using the decoder 210). The SCL decoder may determine input logarithmic-likelihood ratios (LLRs) for the bit channels of the received codeword. During decoding, the SCL decoder may determine decoded LLRs based on these input LLRs, where the decoded LLRs correspond to each bit channel of the polar code. These decoded LLRs may be referred to as bit metrics. In some cases, if the LLR is zero or a positive value, the SCL decoder may determine the corresponding bit is a 0 bit. Alternatively, a negative LLR may correspond to a 1 bit. The SCL decoder may use the bit metrics to determine the decoded bit values.

The SCL decoder may employ multiple concurrent successive cancellation (SC) decoding processes. Each SC decoding process may decode the codeword sequentially (e.g., in order of the bit channel indices). Due to the combination of multiple SC decoding processes, the SCL decoder may calculate multiple decoding path candidates. For example, an SCL decoder of list size ‘L’ (i.e., the SCL decoder has L SC decoding processes) may calculate L decoding path candidates, and a corresponding reliability metric (e.g., a path metric) for each decoding path candidate. The path metric may represent a reliability of a decoding path candidate or a probability that the corresponding decoding path candidate is the correct set of decoded bits. The path metric may be based on the determined bit metrics and the bit values selected at each bit channel. The SCL decoder may have a number of levels equal to the number of bit channels in the received codeword. At each level, each decoding path candidate may select either a 0 bit or a 1 bit based on a path metric of the 0 bit and the 1 bit. The SCL decoder may select a decoding path candidate based on the path metrics, and may output the bits corresponding to the selected decoding path as the decoded sets of bits. For example, the SCL decoder may select the decoding paths with the highest path metrics.

The decoder 210 may improve decoding latency due to LLR derivation and bit feedback if it does not need to perform operations to determine every bit in the decoding path. For example, if a number of sub-channels correspond to known bit values, the decoder 210 may skip performing computations in order to determine hard bit values for the sub-channels. If the decoder 210 determines that the first number of bits are all frozen bits, the decoder 210 may determine that the correct decoding path for the first number of bits are the default values associated with frozen bits (e.g., if the default frozen bit value is 0, the correct decoding path for the first number of bits is determined to be all zeros). Once the decoder 210 reaches the first information bit, the decoder 210 may begin performing operations to decode the rest of the bits of the codeword, as the decoder 210 may not be able to determine the correct decoding path from the first information bit onwards (e.g., because the first information bit may be a 0 or a 1 and represents the first branch in the decoding tree).

In accordance with various aspects of the present disclosure, bit selection schemes that factor reliability of the bit channels as well as decoding complexity may be employed to determine how to allocate the k information bits among the N bits of the codeword. For example, a first scheme may be used for scenarios in which decoding latency and power consumption are key performance indicators (e.g., ultra-reliable low latency communications (URLLC), massive MTC (mMTC), Internet-of Things (IoT), etc.). Because decoding complexity may in some cases be tied to decoding latency and/or power consumption, the first bit selection scheme may weigh reductions in decoding latency more heavily than improvements in reliability. Alternatively, a second bit selection scheme may be used for scenarios in which transmission reliability is a more important performance indicator than decoding latency or power consumption (e.g., enhanced mobile broadband (eMBB) communications). The second bit selection scheme may therefore weight improvements in reliability more heavily than reductions in decoding latency.

Polar codes are characterized by the fact that the decoding complexity has a strong dependency on the location of the information bits (e.g., as opposed to other codes such as tail-biting convolutional codes (TBCCs) in which the decoding complexity is more uniformly distributed across the bit positions). Accordingly, the decoding complexity for any two bit positions (e.g., which may or may not be separated by one or more frozen bits) may vary.

Generally, the techniques described herein support development of a suitable bit selection scheme for a given scenario that sufficiently reflects the relevant factors in the target scenario. If multiple factors (e.g., power consumption, reliability, decoding complexity, etc.) play a role in a target scenario, the polar code for the target scenario may be constructed based on a relevant bit selection scheme. The described techniques include an effective method to capture (and in some cases reduce) the complexity of decoding operations. The described techniques may account for various simplifications in decoding to determine a nominal complexity for various types of decoders. Further considerations for comparing and combining various bit selection schemes are detailed below.

In some cases, aspects of the encoding and decoding techniques described herein may be performed at an entity other than encoder/decoder 210. For example, the entity may be part of wireless communications system 100 or may be independent of wireless communications system 100. The polar codeword structures may, for example, be empirically determined by a special purpose processor (e.g., one designed or configured to implement the various described techniques) or some other suitable entity. This entity may determine a codeword structure for a variety of scenarios (e.g., different N, k, L, transmission type, etc.) based on an optimized combination of decoding complexity/latency and reliability metrics. Communicating devices may then be configured to encode and decode transmissions using the specified codeword structure. For example, communicating devices may be preconfigured (e.g., with a look-up table), semi-statically configured (e.g., through various control signaling such as RRC control signaling), or dynamically configured (e.g., through downlink control information (DCI)) to use a first table for a first communication type (e.g., eMBB) and a second table for a second communication type (e.g., URLLC), where each table specifies a respective bit order, and the tables differ for at least one bit position.

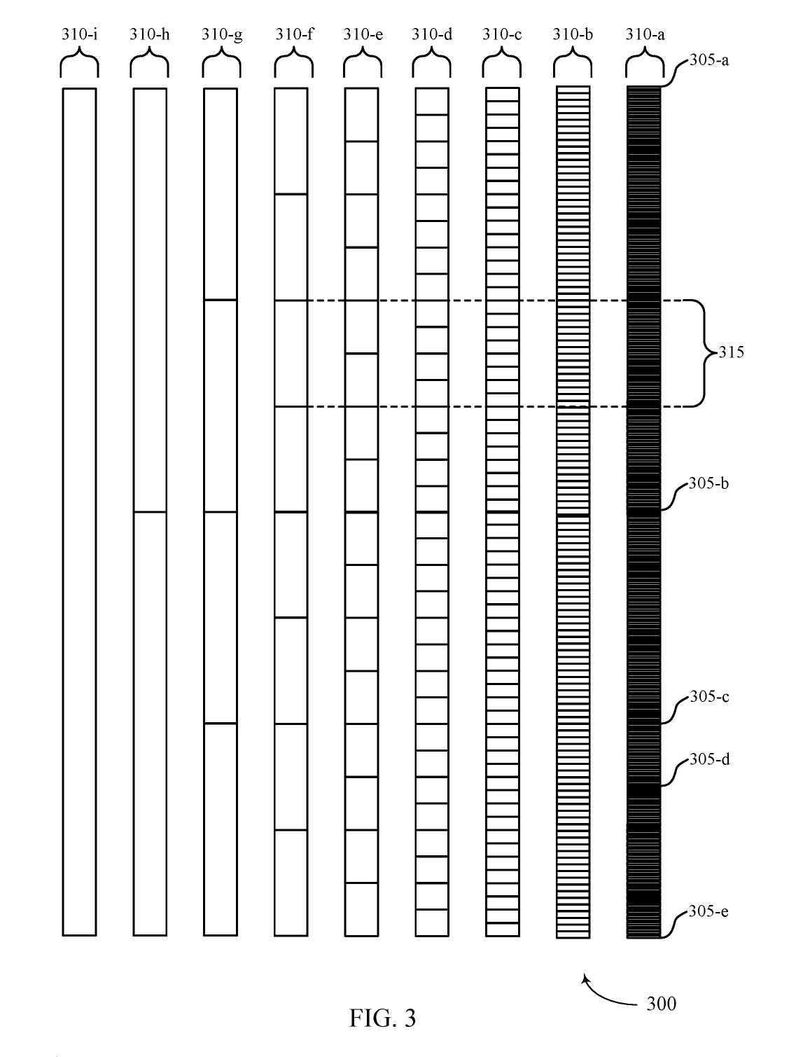

FIG. 3 illustrates an example polar code structure 300 as a convenient way to conceptualize construction of a polar codeword in accordance with various aspects of the present disclosure. Polar code structure 300 includes N (e.g., 256, as illustrated) bit positions 305. Each bit position 305 may be indexed (e.g., such that the top bit position 305-a is indexed 0 and the bottom bit position 305-e is indexed 255). In a given polar code structure of length N, K bit positions 305 may be allocated for information bits. The set of indices associated with these K bit positions 305 may be referred to as a set of information bit channel indices.

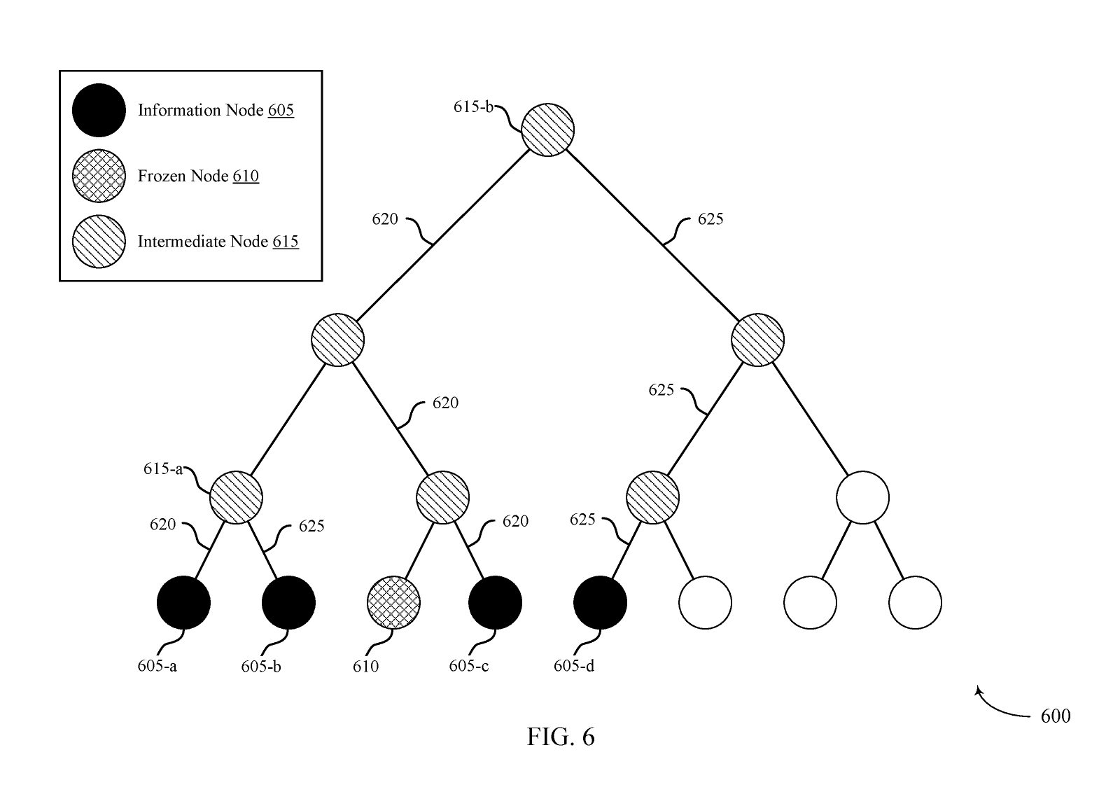

As illustrated, polar code structure 300 contains multiple (e.g., 9 in the present example) layers 310 arranged in a hierarchical fashion. For example, each block in layer 310-i contains two blocks in layer 310-h, four blocks in layer 320-g, etc. In some cases, the layers 310 may be illustrated in a tree structure (e.g., as illustrated below with respect to FIGS. 6 through 8). Accordingly, blocks in intermediate layers 310-h, 310-g, 310-f, 310-e, 310-d, 310-c, 310-b may be referred to as subtrees in various examples. For example, the third block from the top in layer 310-f may be a subtree which spans a set 315 of bit positions 305 (e.g., 32 bit positions 305). Some, all, or none of the bit positions 305 in set 315 may be frozen bits. Layer 310-a may, in some cases, be referred to as the leaf layer.

As discussed above, each bit position 305 may have an associated reliability, and the set of all bit positions 305 may be ranked accordingly. By way of example, the 18 most reliable bit positions 305 may have indices in the set [222 127 237 243 238 245 191 246 249 250 223 252 239 247 251 253 254 255]. In this example and the following description, the indices are included for the sake of explanation only; the concepts may be generalized to other example sets of indices. In polar code structure 300, bit position 305-b has index 127, bit position 305-c has index 191, and bit position 305-d has index 222. Construction of a polar codeword of length 256 that contains 17 information bits in which the only relevant metric is reliability may simply select the indices of the 17 most reliable bit positions 305 (i.e., beginning with bit position 305-b with index 127 and continuing through the end of the set to give [127 237 243 238 245 191 246 249 250 223 252 239 247 251 253 254 255]).

However, as mentioned above, the decoding complexity of a polar codeword is not uniformly distributed across all the bit positions. Accordingly, sets of bit indices that differ only in the inclusion of one or two bit positions 305 may have different (e.g., sometimes significantly different) decoding complexities. By way of example, the set of indices beginning with bit position 305-b (index 127) and continuing through the end of the set may have a significantly higher decoding complexity than the set of indices beginning with bit position 305-d (index 222), excluding bit position 305-b with index 127, and continuing through the end of the set (e.g., [222 237 243 238 245 191 246 249 250 223 252 239 247 251 253 254 255]). For ease of reference, these sets are referred to as a first set and second set, respectively (i.e., the first set contains index 127, while the second set contains index 222 instead).

The first set may have a higher decoding complexity because there are fewer leading frozen bits. That is, for the first set, the bit positions indexed 0 through 126 may be referred to as leading frozen bits. Because these frozen bits do not result in any bit decisions, they may not result in any branches in a decoding tree. Any path metric associated with these frozen bits may be determined based purely on input LLRs with known feedback.

Accordingly, various polar decoding operations such as bit feedback operations, sorting, and list management may be avoided for these frozen bits. This reduction in necessary operations may be associated with a corresponding decrease in complexity and/or latency of decoding. Thus, the second set may allow the decoder to treat the first 191 bit positions 305 (indexed 0 through 190) as leading frozen bits. The increased number of leading frozen bits (e.g., and corresponding decrease in bits after the first information bit for which path metric calculations must be performed) may result in a decreased decoding complexity.

Although introduced in the context of leading information bit position 305 (e.g., 305-b or 305-c in the first and second set, respectively), it is to be understood that the described techniques extend to other bit positions 305 in the set. For example, in some cases, the first set may be modified to include bit position 305-d (index 222) and exclude bit position 305-c (index 191). The modified first set may then have a different (higher or lower) decoding complexity than the original first set. The differences in decoding complexity may be based at least in part on a distribution of intermediate frozen bits (i.e., frozen bits after the first information bit) between the information bit positions 305 of the codeword. Accordingly, in this example and those that follow, frozen bits may be generally categorized as leading frozen bits or intermediate frozen bits (i.e., frozen bits having an index higher than at least one information bit).

In accordance with aspects of the present disclosure, multiple bit selection schemes may be developed and compared in order to determine an optimal information bit set for a given scenario. For example, an optimal information bit set (for a given N:K codeword) may be determined separately for mMTC, URLLC, IoT, and eMBB communication scenarios (e.g., among other communication scenarios). The example first and second set introduced above are used for the sake of explanation.

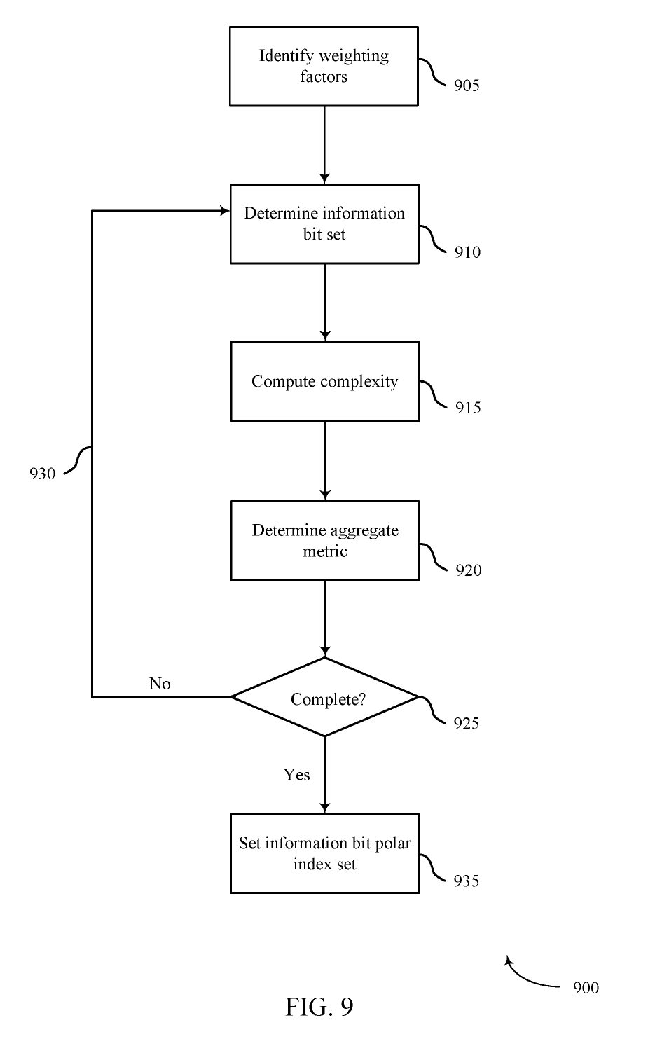

For example, a reliability weight may be applied to the aggregate reliabilities of the information bit positions of each set. Similarly, a complexity weight may be applied to the decoding complexity of the first set and the decoding complexity of the second set. The first reliability metric (e.g., determined based on applying the reliability weight to the aggregate reliabilities of the information bit positions of the first set) may be combined with the first decoding complexity metric (e.g., determined based on applying the complexity weight to the decoding complexity of the first set as a whole) to generate a first aggregate performance metric. Analogous techniques may be employed to generate a second aggregate performance metric (i.e., for the second set). The aggregate performance metrics may then be compared to determine an optimal set of the two sets for a given communication scenario. Iterative simulations may be used to perform a gradient search and determine the optimal set of information bit indices for a given scenario. That is, because of the large number of possible sets, a gradient search (or some other suitable optimization technique) may be employed to select an optimal or satisfactory set (i.e., rather than a brute force comparison of each possible set), as discussed below with reference to FIG. 9.

As an example, the scenario may be URLLC using a given N:K codeword. As mentioned above, URLLC may prioritize decoding complexity (e.g., because of the associated decrease in latency) as a performance indicator. Accordingly, for URLLC, the reliability weight and/or complexity weight may be appropriately scaled to bias the search towards sets with smaller decoding complexity metrics. Alternatively, the scenario may be eMBB communications using the same N:K codeword. As mentioned above, eMBB communications may prioritize reliability as a performance indicator. Accordingly, for eMBB communications, the reliability weight and/or complexity weight may be appropriately scaled to bias the search towards sets with larger reliability metrics.

Because comparison of weighting schemes is based at least in part on an estimate of the decoding complexity, techniques for efficient estimation of decoding complexity are described herein. These techniques may be extended to provide similar reductions in decoding complexity in practice (e.g., which may benefit a decoder with power or computational constraints), as described further below.

In some cases, the various weights themselves may be determined through iterative simulations. That is, through simulation, complexity weighting for each of the information bits given a set of parameters (e.g., N, K, L, puncturing, weighting from other schemes, etc.) can be derived. The weights may be used to form polar codeword structures that account for factors beyond a simple reliability ranking (e.g., also consider decoding complexity). Accordingly, different weights may represent different tradeoffs which may be used by encoder-decoder pairs to communicate more efficiently in different use cases.

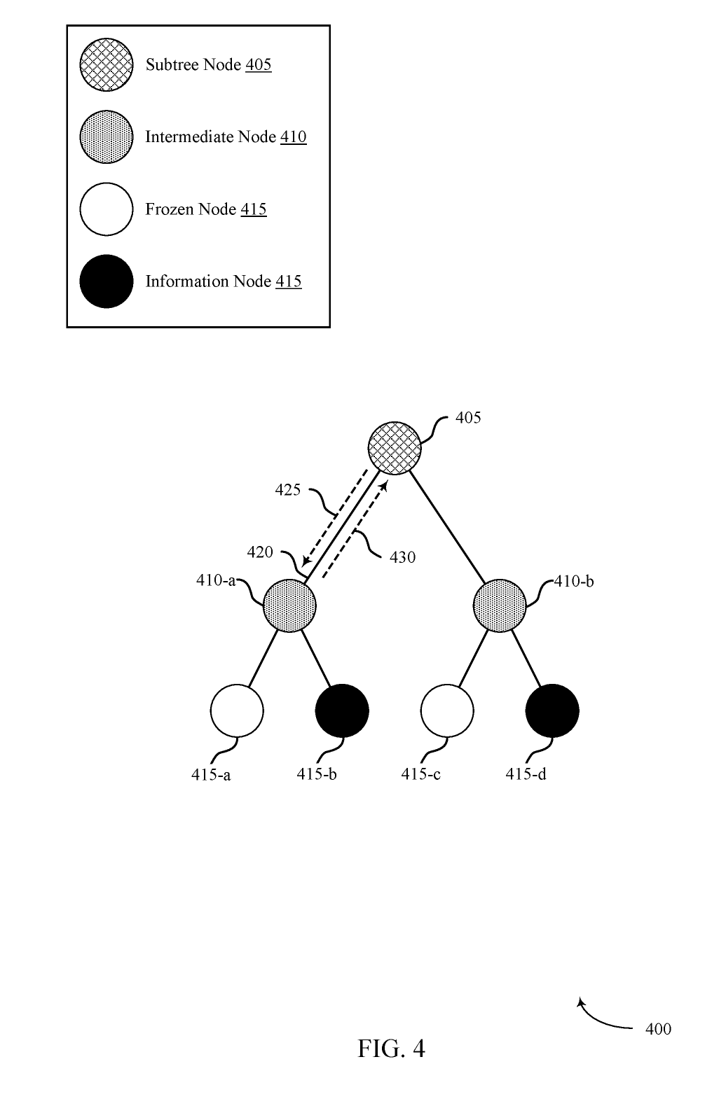

FIG. 4 illustrates an example of a polar code subtree 400 in accordance with various aspects of the present disclosure. Polar code subtree 400 may illustrate aspects of polar code structure 300. For example, polar code subtree 400 contains a single subtree node 405 from a first layer (e.g., layer 310-c of FIG. 3), two intermediate nodes 410 from a second layer (e.g., layer 310-b of FIG. 3), and four leaf nodes 415 from a third layer (e.g., leaf layer 310-a of FIG. 3). As illustrated, each leaf node 415 may be an information node or a frozen node.

Decoding schemes may vary across decoders (e.g., SC decoders, SCL decoders, software decoder, hardware decoders, etc.). However, the different decoding schemes may share a common set of operations. These common operations may comprise a majority of the complexity involved in the decoding operations, such that comparing the operations across different decoding schemes may provide an adequate estimate of the comparative decoding complexities.

For example, decoding operations at a SC decoder and/or SCL decoder may generally be organized into three categories: non-leaf-layer LLR derivations, leaf node operations (e.g., LLR derivations, list management, sorting, etc.), and bit feedback operations. Operations in these categories may comprise a majority of the complexity involved in successive cancellation decoding schemes. SCL decoders may in some cases include additional decoding operations. For example, in an SCL decoder, intermediate frozen bits (i.e., frozen bits that have indices larger than an information bit) may incur unequal LLRs across list members and may therefore be included in run-time computations for path metric updates. Additionally or alternatively, in an SCL decoder, since processing for each new information bit involves doubling the number of path candidates, certain list sorting by the path metrics and selection for the top L path candidates may be needed. Further, in some SCL decoders, since sorting and selection are involved in processing for each new information bit, the ordering of the list members may be properly reflected in the list as well as in the feedback bits kept in each active branch of a layer.

While these SCL-specific operations represent potential differences in decoder implementation from one decoder variation to another, the fundamental polar decoder properties organized into the three categories above may be common to SC and SCL implementations. Accordingly, in determining decoding complexity for polar code construction (e.g., to compare performance of different polar codes), capturing the nominal complexity of these primary decoding operations may be sufficient. As illustrated, for a given branch 420 of the polar code subtree 400, LLR derivations may flow in a direction 425 (e.g. to determine a bit hypothesis) while bit feedback operations may flow in a direction 430 (e.g., to return the decoded bit hypothesis such that a subsequent LLR derivation may use the decoded bit hypothesis).

For the non-leaf layer LLR derivations, the major factor in determining decoding latency and complexity is the number of nodes over which to operate. For example, given any two consecutive indices ‘i’ and ‘i+1’ in the range of [0,K−1] for any two information bits and their locations in the range of [0, N−1], the nominal complexity for LLR derivations can be derived (e.g., assuming that all bits between the two information bits are frozen bits). The nominal complexity of this category can cover the number of F and G operations for the decoding scheme.

Bit feedback operations primarily comprise exclusive-or (XOR) operations. The number of XOR operations depends primarily on the layer of the subtree node 405 that covers the adjacent information nodes (e.g., leaf nodes 415-b and 415-d). The nominal complexity of this category can cover the amount of XOR operations needed for feedback messaging.

The difference in decoding complexity for a given leaf node 415 across decoding variations is relatively small. For example, list management and sorting may occur at any information leaf node, regardless of the location of that information node relative to other information nodes. Accordingly, for a codeword of a given length with a given number of information bits, the variation in decoding complexity across various polar code constructions may be relatively small. It may thus be possible to ignore (e.g., or discount) the effects of leaf node operations on the estimated decoding complexity.

Each of these sets of operations may be associated with a given relative complexity. For example, bit feedback operations may be less computationally complex than non-leaf layer LLR derivations, such that an increase in the number of bit feedback operations that accompanies a corresponding decrease in the number of non-leaf layer LLR derivations may still decrease the overall complexity of the decoding operation. In some cases, a complexity weighting factor may be applied to the aggregate number of bit feedback operations and non-leaf layer LLR derivations (e.g., such that the two types of operations are treated equally). Alternatively, individual weights may be applied to each type of operation before an aggregate complexity metric is determined.

Through iterative simulations, complexity weighting for each of the information bits (e.g., given the known parameter set N, K, L) can be derived. Iterations may be used to update the resultant complexity. If higher order accuracy is needed in nominal complexity derivation, more details of operations may be considered (e.g., the SCL-specific operations discussed above). The nominal complexity derivation may adopt certain suitable decoding operation simplification schemes, as detailed below.

In order to support nominal complexity comparison of weightings from multiple schemes, various metrics may be derived and compared across multiple weighting schemes. For example, given a set of parameters (e.g., including N, K, L, and the weighting from other polar characteristics such as bit reliability), a set of metrics may be developed. Example metrics include a nominal complexity of decoding for each information bit and an effective scaling factor among multiple weighting schemes. Based on comparisons of these metrics, an update (e.g., modification) in information bit locations may be determined to find improvements in the overall weighted performance. In some cases, iterations may be used in the process of combination and modification before a stable weighting is derived on a given parameter set. In the case that a certain metric needs to be completely eliminated (i.e., ignored) from the final weighting scheme, the scaling factor for that metric may be set to zero. For example, assuming that both reliability weighting and complexity weighting are available (e.g., and only the reliability weighting needs to be considered in a target scenario), the scaling factor for complexity weighting metric may be set to zero. An iterative scheme as described herein can be seen as a generalized method to factor multiple metrics into different weighting schemes.

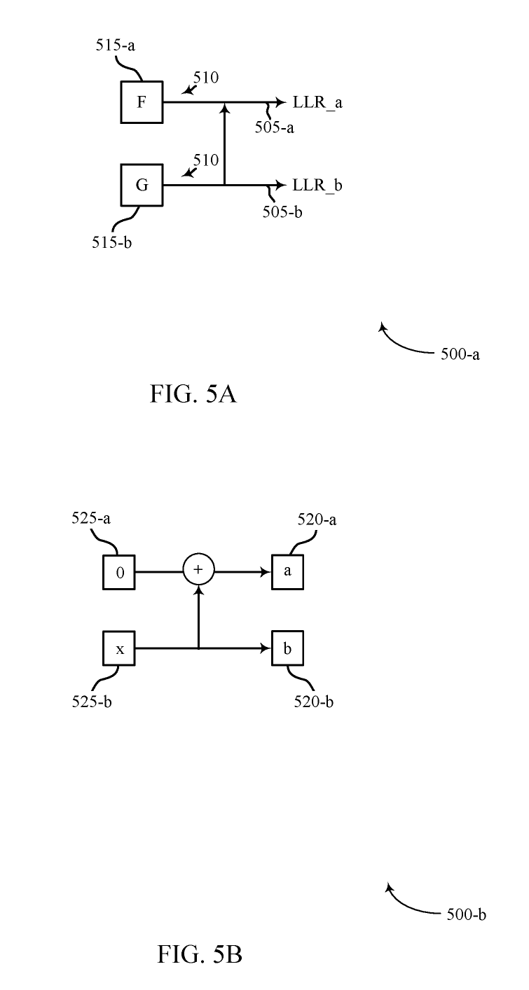

FIG. 5A illustrates an example of a coder/decoder (codec) segment 500-a that supports various aspects of the present disclosure. The codec segment 500-a may be implemented in a receiver, such as a receiver included in a UE 115 or base station 105 described with reference to FIG. 1. For example, the codec segment 500-a may be performed by the encoder/decoder 210 described with reference to FIG. 2. Codec segment 500-a illustrates an example 2-bit decoder. Codec segment 500-a illustrates operations performed to propagate LLRs through a polar codec. Because of the construction of the codec segment 500-a (e.g., a SC/SCL construction), the relative capacities of the input bit-channels (with arrows drawn in the encoding direction) may be different than the output bit-channels.

The plurality of input LLRs 505 for codec segment 500-a may be received corresponding to a plurality of interconnected bit-channels 510. By way of example, codec segment 500-a is shown to perform one F operation and one G operation. Each F operation may receive an operand LLR_a 505-a (associated with a less significant (e.g., reliable) bit position or XOR'd bit position) and an operand LLR_b 505-b (associated with a more significant bit position or non-XOR'd bit position) and obtain the output LLR 515-a by performing a polar code single parity check (SPC) decoding operation (e.g., F operation):

F(LLR_a,LLR_b)=Sign(LLR_a)×Sign(LLR_b)×min(|LLR_a|,|LLR_b|)

The output LLR 515-a may represent a decoded bit value (e.g., 0 or 1). Based on the sign of the LLR 515-a and an expected value for the decoded bit, the codec segment 500-a may assign one or more decoded bit values for the output bit-channel. For example, if the output LLR 515-a is negative, the output bit-channel may be assigned a decoded bit value of 1. If the output LLR 515-a is greater than or equal to 0, the output bit-channel may be assigned a decoded bit value of 0. In some cases, if the expected bit value for the output bit-channel is different from the decoded bit value corresponding to the LLR 515-a, the output bit-channel may be assigned to the expected bit value and the path metric corresponding to the output bit-channel is updated based on the LLR 515-a.

The assigned value for the output bit-channel may then be used as a feedback bit for a G operation. In some cases, the assigned value for the output bit-channel may be fed back to be used (e.g., in an XOR operation) to determine an output bit value for an F operation that corresponds to the G operation. Each G operation may receive operand LLR_a 505-a and operand LLR_b 505-b and obtain the output LLR 515-b by performing a polar code repetition decoding operation (e.g., G operation):

G(LLR_a,LLR_b)=LLR_b+LLR_a if b=0=LLR_b−LLR_a if b=1

where b is equal to the determined output bit value for the corresponding F operation.

FIG. 5B illustrates an example of a codec segment 500-b that supports various aspects of the present disclosure. As with codec segment 500-a, codec segment 500-b may be implemented in a receiver, such as a receiver included in a UE 115 or base station 105 as described with reference to FIG. 1. For example, the codec segment 500-b may be performed by the encoder/decoder 210 described with reference to FIG. 2.

Codec segment 500-b contains two LLRs 520-a and 520-b. Based on the LLR derivations (e.g., F operations and G operations) described with reference to FIG. 5A, bit decisions 525 may be determined. For example, bit decision 525-a may represent the output of the F operation of the LLRs 520, while bit decision 525-b may represent the output of the G operation, which takes bit decision 525-a as an input.

Iteratively performing codec segment 500-b over the course of a polar codeword represents one viable solution for polar decoding. However, the complexity of the decoding operation may in some cases be reduced using simplifications described herein. For example, in some cases, bit decisions 525-a and 525-b may correspond to frozen bit locations (e.g., which have a value of zero). A number of LLR derivations and bit feedback operations for such a codec segment 500-b may be reduced.

TABLE 1

| Condition | Sub-Condition | BM₀ | BM₁ | PM |
|---|---|---|---|---|
| a ≥ 0 && b ≥ 0 | N/A | 0 | 0 | 0 |
| a ≥ 0 && b < 0 | \|a\| ≥ \|b\| | \|b\| | 0 | \|b\| |
| | \|a\| < \|b\| | \|a\| | \|b\| − \|a\| | \|b\| |
| a < 0 && b ≥ 0 | \|a\| ≥ \|b\| | \|b\| | \|a\| − \|b\| | \|a\| |
| | \|a\| < \|b\| | \|a\| | 0 | \|a\| |
| a < 0 && b < 0 | N/A | 0 | \|a\| + \|b\| | \|a\| + \|b\| |

Table 1 illustrates a pattern which may be exploited to simplify decoding operations. Table 1 considers a scenario in which a given subtree has rate zero (i.e., the subtree has no information bits). The example is described in terms of a 2-bit decoder, though the concept may be extended to larger subtrees. In some cases, larger subtrees may be used as long as they only contain a single information bit (e.g., as described with reference to Table 2). In the following examples, a negative LLR is assumed to generally correspond to a bit decision of 1 while a positive LLR is assumed to correspond to a bit decision of 0; the decoder may correlate larger LLR magnitudes (e.g., positive or negative) with a stronger bit hypothesis.

As illustrated in Table 1, when LLR 520-a (e.g., represented in the table as ‘a’) and LLR 520-b (e.g., represented in the table as ‘b’) are both non-negative, the path metric for the codec segment 500-b may be zero. That is, because both LLRs 520 are non-negative, they may be decoded (e.g., using F and G operations) as corresponding to zero bits. Because bit decisions 525-a and 525-b represent intermediate frozen bits (e.g., which are known to have a value of zero), the LLRs 520 may not conflict with the frozen bits. Accordingly, the path metric (which represents the sum of the branch metrics BM₀ and BM₁) may be zero. Because the path metric represents a penalty for a given decode path, non-negative LLRs 520 for a rate zero subtree may be associated with an optimal path (e.g., with no penalty).

However, as illustrated in the second condition set, a scenario may arise in which LLR 520-a is non-negative while LLR 520-b is negative. Accordingly, a non-zero path metric may apply. As illustrated, two sub-conditions may apply: a first in which the magnitude of LLR 520-a is greater than or equal to that of LLR 520-b, and a second in which the magnitude of LLR 520-a is less than that of LLR 520-b. As illustrated above with respect to FIG. 5A (e.g., the F-operation), BM₀ may be computed as the smaller of the two LLRs 520. BM₁ may then be zero or the difference between the two LLRs 520 (e.g., in the case that the sign-conflicting LLR 520-b is not the smaller of the two LLRs 520 as in the case of the second sub-condition). In either case, it is shown that the path metric (e.g., which represents the sum of the two branch metrics) has the magnitude of LLR 520-b (i.e., the sign-conflicting LLR 520). LLR 520-b is referred to as a sign-conflicting LLR 520 because its negative value conflicts with the expected positive LLR value for a frozen bit.

Analogous computations may be carried out for the third and fourth conditions. In each case, the resulting path metric represents the sum of the LLR magnitudes of any sign-conflicting LLRs 520. Accordingly, rather than performing LLR derivations and bit feedback operations in order to determine a path metric for a given subtree, the path metric may be more easily computed based on the input LLRs 520.

TABLE 2

| | Sub- | | | |
|---|---|---|---|---|
| Condition | Condition | BM₀ | BM₁ | PM |
| a ≥ 0 && b ≥ 0 | N/A | 0 | {x=0}: 0 | {0, 0}: 0 |
| | | | {x=1}: \|a\| + \|b\| | {0,1}: \|a\| + \|b\| |
| a ≥ 0 && b < 0 | \|a\| ≥ \|b\| | \|b\| | {x=0}: 0 | {0, 0}: \|b\| |
| | | | {x=1}: \|a\| − \|b\| | {0,1}: \|a\| |
| | \|a\| < \|b\| | \|a\| | {x=0}: \|b\| − \|a\| | {0, 0}: \|b\| |
| | | | {x=1}: 0 | {0,1}: \|a\| |
| a < 0 && b ≥ 0 | \|a\| ≥ \|b\| | \|b\| | {x=0}: \|a\| − \|b\| | {0, 0}: \|a\| |
| | | | {x=1}: 0 | {0,1}: \|b\| |
| | \|a\| < \|b\| | \|a\| | {x=0}: 0 | {0, 0}: \|a\| |
| | | | {x=1}: \|b\| − \|a\| | {0,1}: \|b\| |
| a < 0 && b < 0 | N/A | 0 | {x=0}: \|a\| + \|b\| | {0, 0}: \|a\| + \|b\| |
| | | | {x=1}: 0 | {0,1}: 0 |

The simplifications for a rate zero subtree may be extended to a subtree that contains a single information bit, as illustrated with respect to Table 2. Because of the nature of a polar code, the last bit location of a given subtree will contain the information bit (e.g., because the last bit location will be the most polarized, and therefore the most reliable bit location of the subtree). The BM₁ computations for Table 2 are complicated by the fact that bit decision 525-b may be a 0 or a 1. Accordingly, multiple path metrics must be calculated in order to make a decision. However, the same principles described with reference to Table 1 apply. For example, for any given condition, the path metric for a given bit decision 525-b represents the sum of any sign-conflicting LLRs 525. As an example, looking at the first sub-condition of the third condition, BM₀ is shown to be |b| (i.e., because there is a sign-conflicting LLR value, and LLR 520-b is smaller than LLR 520-a). In the case that bit decision 525-b is a 0, BM₁ is shown to be |a|−|b|. In the case that bit decision 525-a is a 1, BM₁ is shown to be 0. In each case, a path metric is computed as the sum of BM₀ and BM₁. The path metrics may be used in list management and sorting operations at the leaf node.

These simplifications may be generalized to larger decoding blocks. With such simplifications, the need for recursive F and G operations down to the lowest level of a tree to derive bit LLRs may be eliminated. Rather, equivalent block LLRs may be directly derived at a higher level using the sum of the absolute value of all sign-conflicting LLRs in the block.

In aspects, the terms blocks (e.g., decoding blocks) and subtree (e.g., polar code subtree 400 as discussed with reference to FIG. 4) may be used interchangeably. As the subtree size grows, there will be larger sets of combinations at the top of the subtree; more combinations means more hypotheses to consider, which may increase implementation difficulties. Nominal complexity for LLR derivation with the block LLR method may therefore be applicable if the subtree has a number of information bits below a certain threshold (e.g., fewer than two information bits). One reason for such a constraint is that sorting and permutations for SCL will be involved for a subtree that has more than one information bit. Resultant LLRs over the list for SCL may then have to undergo operations that may not be typical or common in SCL decoding. However, the described techniques may in some cases be extended to cover the scenario in which multiple information bits are contained within a subtree if it is deemed suitable for nominal complexity for LLR derivation. In some examples, the complexity of different operation categories may be combined with weighted sums, before being further combined with other weighting factors (e.g., reliability). The weights may be derived through simulation and further based on the selection of modeling characteristics and the targeted scenarios. As used herein, a weighted combination refers to a combination in which the aggregate weighted metrics for each of the combined metrics are equal or a combination in which the aggregate weighted metrics for different metrics are unequal (e.g., differ slightly, substantially differ, vary by orders of magnitude, have different signs).

FIG. 6 illustrates an example polar tree 600. Polar tree 600 contains four layers of nodes connected in a hierarchical fashion and may be implemented at an encoder or decoder as described above. By way of example, polar tree 600 contains four information bit nodes 605-a, 605-b, 605-c, 605-d and one intermediate frozen node 610. Each of these nodes may represent a leaf layer node, as described above with reference to FIG. 3. Decoding of the codeword associated with polar tree 600 may be based in part on processing (e.g., sorting) path metrics associated with the various information bit nodes (e.g., which may represent branch points for the decoding operation).

As illustrated, information bit nodes 605-a and 605-b are adjacent (e.g., have adjacent indices), as are information bit nodes 605-c and 605-d. However, the decoding complexity of the separate pairs of information bit nodes may be significantly different (e.g., even though both pairs contain adjacent indices). Such differences illustrate the effect that the tree traversal depth has on the decoding complexity. For example, information bit nodes 605-a and 605-b are contained under a single intermediate node 615-a at an immediately preceding layer. Accordingly, decoding of information bit node 605-b may involve a single bit feedback operation 620 and a single LLR derivation 625. For list size L, such a decoding operation involves L bits of update and feedback and L LLR derivations.

Alternatively, information bit nodes 605-c and 605-d are contained under a single intermediate node 615-b that is multiple layers higher. Intermediate node 615-b is illustrated as being at the top of polar tree 600; however it is to be understood that polar tree 600 may represent a subset of the decoding tree for the entire codeword. In order to decode information bit node 605-d, three bit feedback operations 620 may be involved, along with three LLR derivations 625. For list size L, such a decoding operation involves 7*L bits of update and feedback and 7*L F or G operations for LLR derivations. In these examples, the 7 comes from the aggregated number of bits at each level (e.g., 1 bit from the leaf layer, 2 from the second layer, 4 from the third layer, etc.). Accordingly, because the tree traversal depth of the second pair of information bit nodes is greater than the tree traversal depth of the first pair of information bit nodes, the second pair of information bit nodes may be associated with a greater decoding latency (e.g., or complexity).

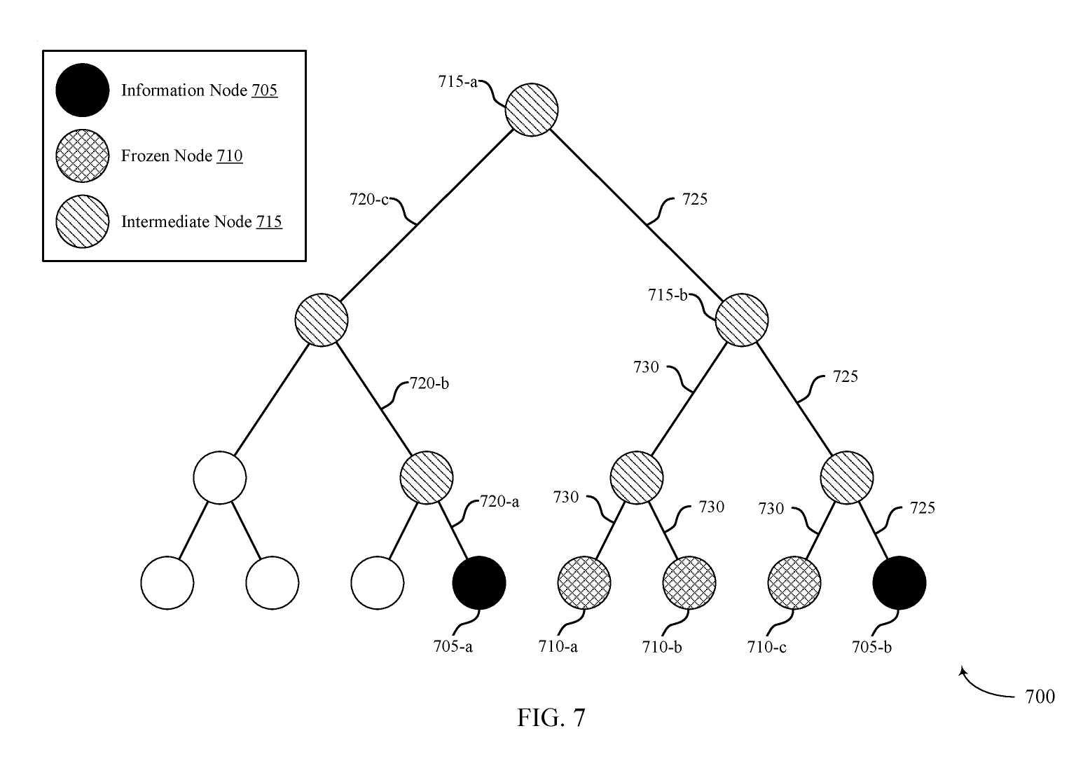

FIG. 7 illustrates an example polar tree 700. Polar tree 700 contains four layers of nodes connected in a hierarchical fashion and may be implemented at an encoder or decoder as described above. By way of example, polar tree 700 contains two information bit nodes 705-a and 705-b, which are separated by three intermediate frozen bits 710-a, 710-b, 710-c. After a bit hypothesis for information bit node 705-a is determined, there may be multiple feedback operations and LLR derivations associated with determining a bit hypothesis for information bit node 705-b. For example, there may be three bit feedback operations 720 from information bit node 705-a to intermediate node 715-a. Each bit feedback operation 720 may be comprised of multiple sub-operations and each of the multiple sub-operations may include a single feedback bit.

The number of sub-operations within a given bit feedback operation 720 may depend on the tree traversal depth at which the bit feedback operation is performed. Accordingly, the three feedback operations 720-a, 720-b, 720-c may contain 1, 2, and 4 bits of feedback, respectively, such that the feedback from information bit node 705-a to intermediate node 715-a contains a total of 7 bits of feedback. An LLR derivation 725 may be performed between intermediate node 715-a and intermediate node 715-b. As with the bit feedback operations 720, each LLR derivation 725 may contain multiple sub-processes in parallel depending on the tree traversal depth at which the operation is performed (e.g., such that the LLR derivation 725 between intermediate node 715-a and intermediate node 715-b may contain four such sub-processes. Under intermediate node 715-b, there may be multiple LLR derivation and feedback operations 730 in order to determine path metrics for the intermediate frozen bits 710-a, 710-b, and 710-c. Additional LLR derivations 725 may be performed in order to determine the bit hypothesis for information bit node 705-b. Such a decoding scheme may use 12*L bits of update and feedback and 12*L F or G operations for LLR derivations.

In some cases, the location of indices of information bit nodes 705-a, 705-b may be determined based on a given weighting scheme, as described above. However, in order to compare weighting schemes and improve the performance of the various decoding operations, simplifications (e.g., subtree pruning) may be employed.

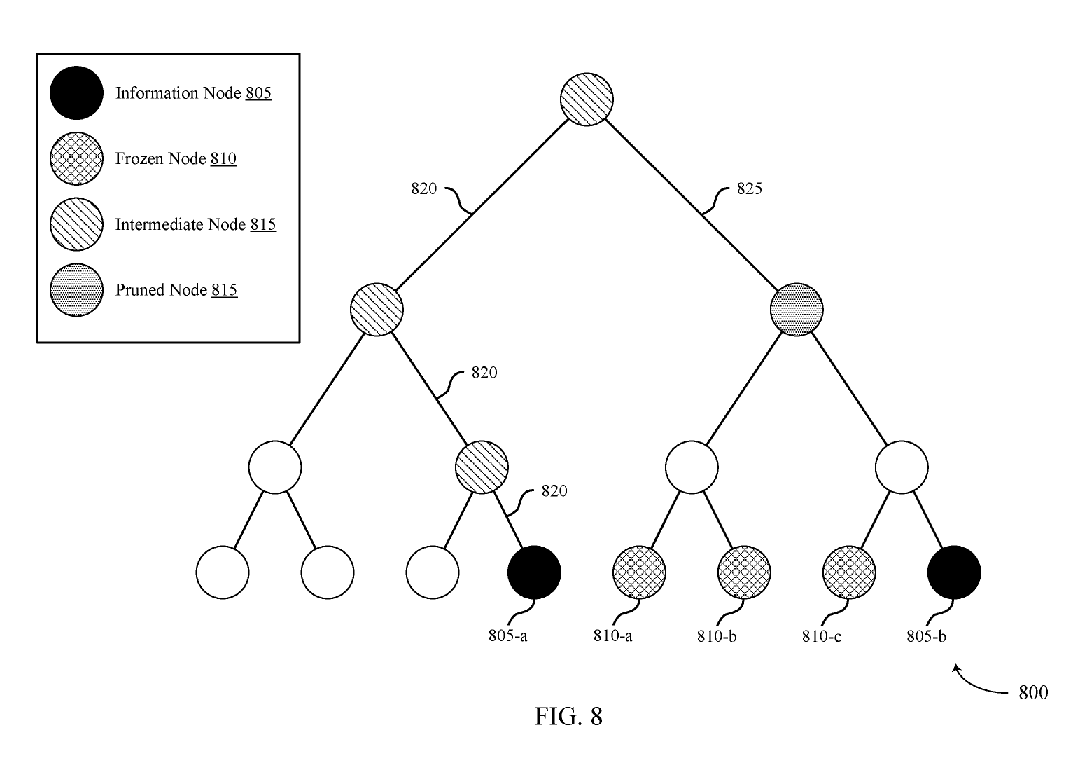

FIG. 8 illustrates an example polar tree 800, which may be an example of polar tree 700. Polar tree 800 contains four layers of nodes connected in a hierarchical fashion and may be implemented at an encoder or decoder as described above. By way of example, polar tree 800 contains two information bit nodes 805-a and 805-b, which are separated by three intermediate frozen bits 810-a, 810-b, 810-c.

Decoding of polar tree 800 may employ subtree pruning, as described with reference to FIGS. 5A and 5B. Accordingly, the nodes under pruned node 815 may be treated as a single LLR_block. That is, path metrics for information bit node 805-b may computed as the sum of the absolute values (i.e., magnitudes) of all sign-conflicting LLRs. Such a simplification may allow the decoding operation to use 7*L bits of update and feedback (e.g., instead of the 12*L bits of update and feedback employed for polar tree 700), 4*L F or G operations for LLR derivation (e.g., instead of the 12*L F or G operations for LLR derivation employed for polar tree 700), and 8*L summations for the four nodes at the pruned node 815 over the two hypotheses. As described above, the reduced complexity of the decoding of polar tree 800 may be used in practice at a decoder as well as in developing the optimal polar code for a given target scenario (e.g., in comparing different polar code constructions).

FIG. 9 illustrates an example process flow 900 that supports nominal complexity and weighted combinations for polar code construction in accordance with various aspects of the present disclosure. The operations of process flow 900 may be implemented by a UE 115, base station 105, or device 200 as described herein. Additionally or alternatively, the operations of process flow 900 may be implemented by one or more processors (e.g., configured to simulate performance of a wireless communications system).

The number of permutations for a set of polar channel indices within a codeword may be large. As an example, a codeword may contain 256 information bits, of which 16 are allocated as information bits. In such a scenario, the number of potential information bit polar index sets (i.e., the number of groups of 16 indices in which at least one index differs between each set) is on the order of 10³⁸. In some cases, restrictions may be implemented to reduce the number of potential sets. Regardless, comparison of performance between each different potential set of indices may be computationally rigorous. In accordance with aspects of the present disclosure, various optimization techniques may be employed to determine a satisfactory set of information bit indices.

At 905, weighting factors for the relevant metrics (e.g., reliability and complexity) may be identified. In some cases, these weighting factors may be based on empirical considerations. For example, given a set of parameters N, K, and L along with a type of communication (e.g., URLLC, eMBB, etc.), a set of relevant metrics as well as weighting factors for one or more of these metrics may be determined. The weighting factors may be chosen pseudo-randomly or based on some previously determined set of weighting factors (e.g., a suitable set of weighting factors for a set of parameters having the same N and L values but different K). In some cases, the weighting factors may be selected such that only metrics within a certain range are weighted (e.g., the weighting factor may resemble a step function such that a latency for a set of information bits that is too high to be feasible or too low to enable sufficient reliability may be ignored). In some cases, the weighting factors themselves may be optimized (e.g., by maintaining a constant set of information bit indices and comparing the results of the various weighting schemes to empirical or simulated performance). However, for the sake of explanation, the process flow 900 shows a process for determining an information bit polar index set based on known weighting factors.

At 910, an information bit set for performance testing may be determined. In some cases, the initial information bit set may be associated with the set of maximum-reliability information bit locations. Optimization of this initial information bit set may be performed in an iterative fashion (e.g., by modifying one information bit index at a time). Example optimization techniques are discussed further below.

At 915, a complexity metric for the determined set of information bits may be computed. As described above, the complexity metric may apply to the codeword as a whole or in some cases may be an aggregate of complexity metrics associated with each information bit position. For example, a given information bit position may be covered by a subtree (e.g., or block) of the decoding tree. The decoding complexity of this block may be estimated using any of the techniques described above (e.g., the block LLR simplification techniques). In some cases, various decoding operations may factor into the complexity metric separately. For example, the bit feedback operations of a given subtree may be weighted by a first factor while the non-leaf layer LLR derivations of the same subtree may be weighted by a second factor different from the first. The aggregate number of weighted decoding operations may then factor into the computation of the complexity metric. Because decoding complexity may depend not only on the indices included in the information bit set, but also on the relationship between these indices, any update in the information bit set at 910 may involve a separate complexity metric computation at 915.

At 920, an aggregate metric for the set of information bits may be computed. In some cases, the aggregate metric includes a weighting factor applied to the complexity metric at 915 and a second weighting factor applied to an aggregate reliability metric (e.g., which may be determined based on the sum of the reliabilities of the information bit positions included in the set).

At 925, a decision may be made as to whether the optimization process is complete. The decision at 925 may be based in part on the type of optimization process that is employed. Various optimization techniques are considered within the scope of the present application. For example, a gradient search may be employed in which the marginal improvement over a previous result influences the subsequent modified information bit set selection. In another example, a Monte Carlo tree search may be employed (e.g., in which each branch on the tree represents changing one information bit to a different index). In some cases, the gradient search or Monte Carlo tree search may be performed pseudo-randomly or with back-propagation to expand different nodes of the tree search (e.g., nodes with promising aggregate metrics).

Additionally or alternatively, branch and bound techniques for pruning the search tree may be used (e.g., minimax pruning, naïve minimax pruning, alpha-beta pruning). Further, combinatorial optimization techniques may be used such as dynamic programming to compute the optimal or near-optimal (e.g., based on maximizing the aggregate metric) selection of an information bit polar index set. In some examples, approximate programming techniques may be used to reduce computational complexity. For instance, approximations (e.g., rounding, truncating precision) in reliability, complexity, etc. may be employed to bound the solution space. In some examples, constrained optimization may be employed (e.g., such that performance is optimized with respect to some variables in the presence of constraints on other variables). The constrained variable may be, for example, a decoding complexity and/or a reliability threshold. For example, for URLLC type communications, the decoding latency may be determined by a latency metric that reflects a latency constraint for processing control information within a given time (e.g., number of symbol periods, etc.) and the process flow 900 may be used to find an information bit polar index set that meets the decoding latency constraint with an optimized aggregate reliability metric.

If the optimization process is not determined to be complete, the process flow may return to 910. In some cases, the information bit set determined at 910 may be based at least in part on some feedback information 930 (e.g., back-propagation) in accordance with various optimization techniques. If the optimization process is determined to be complete, the optimized information bit polar index set may be identified for the given parameters (e.g., N, K, L, and weighting factors) at 935.

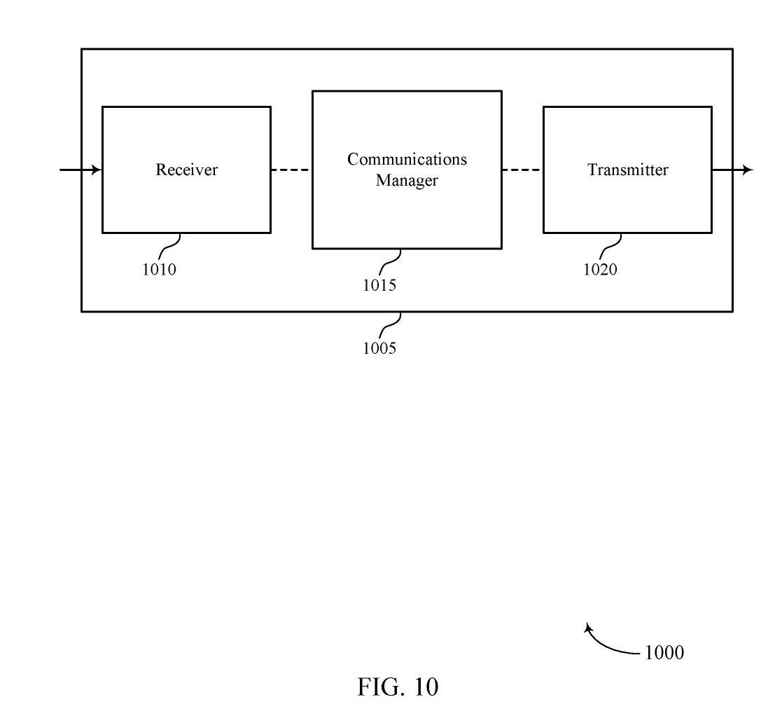

FIG. 10 shows a block diagram 1000 of a wireless device 1005 that supports nominal complexity and weighted combinations for polar code construction in accordance with aspects of the present disclosure. Wireless device 1005 may be an example of aspects of a UE 115, base station 105, or device 200 as described herein. Wireless device 1005 may include receiver 1010, communications manager 1015, and transmitter 1020. Wireless device 1005 may also include a processor. Each of these components may be in communication with one another (e.g., via one or more buses).

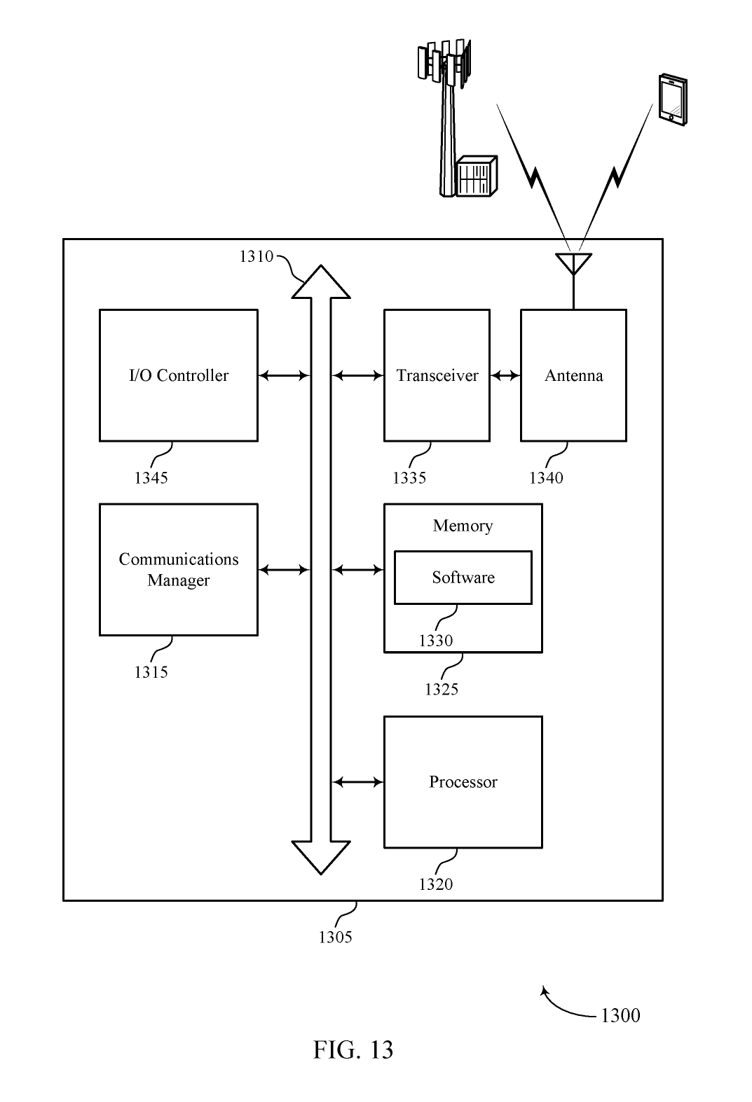

Receiver 1010 may receive information such as packets, user data, or control information associated with various information channels (e.g., control channels, data channels, and information related to nominal complexity and weighted combinations for polar code construction, etc.). The receiver 1010 may be an example of aspects of the transceiver 1335 described with reference to FIG. 13. The receiver 1010 may utilize a single antenna or a set of antennas. Information may be passed on to other components of the device.

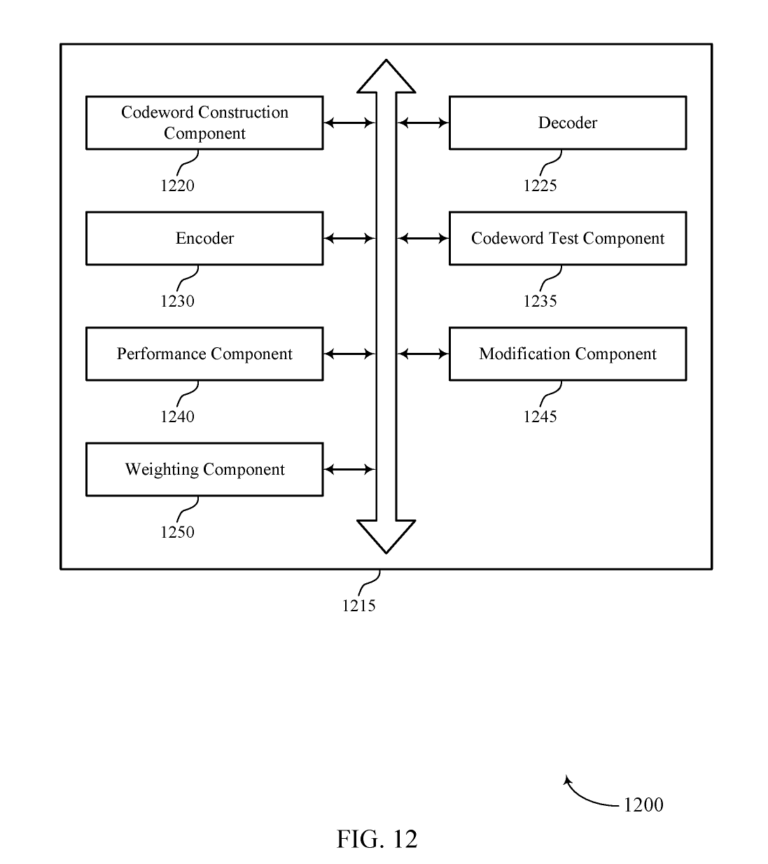

Communications manager 1015 may be an example of aspects of the communications manager 1215 described with reference to FIG. 12. Communications manager 1015 and/or at least some of its various sub-components may be implemented in hardware, software executed by a processor, firmware, or any combination thereof. If implemented in software executed by a processor, the functions of the communications manager 1015 and/or at least some of its various sub-components may be executed by a general-purpose processor, a digital signal processor (DSP), an application-specific integrated circuit (ASIC), an field-programmable gate array (FPGA) or other programmable logic device, discrete gate or transistor logic, discrete hardware components, or any combination thereof designed to perform the functions described in the present disclosure.

The communications manager 1015 and/or at least some of its various sub-components may be physically located at various positions, including being distributed such that portions of functions are implemented at different physical locations by one or more physical devices. In some examples, communications manager 1015 and/or at least some of its various sub-components may be a separate and distinct component in accordance with various aspects of the present disclosure. In other examples, communications manager 1015 and/or at least some of its various sub-components may be combined with one or more other hardware components, including but not limited to an I/O component, a transceiver, a network server, another computing device, one or more other components described in the present disclosure, or a combination thereof in accordance with various aspects of the present disclosure.

The communications manager 1015 may support encoding and/or decoding operations as described herein. For example, communications manager 1015 may receive a codeword encoded using a polar code, the codeword generated based on a plurality of information bits. Communications manager 1015 may identify a set of polar bit channel indices corresponding to the plurality of information bits, where each polar bit channel index of the set of polar bit channel indices is selected from a plurality of polar bit channel indices of the polar code based on a reliability metric and a decoding complexity metric associated with the set of polar bit channel indices. Communications manager 1015 may decode the codeword to obtain the plurality of information bits based on the set of polar bit channel indices. Additionally or alternatively, communications manager 1015 may encode the set of information bits according to the polar code based on the set of polar bit channel indices to obtain a codeword.

Transmitter 1020 may transmit signals generated by other components of the device. In some examples, the transmitter 1020 may be collocated with a receiver 1010 in a transceiver module. For example, the transmitter 1020 may be an example of aspects of the transceiver 1335 described with reference to FIG. 13. The transmitter 1020 may utilize a single antenna or a set of antennas. Transmitter 1020 may transmit the codeword encoded by the communications manager 915.

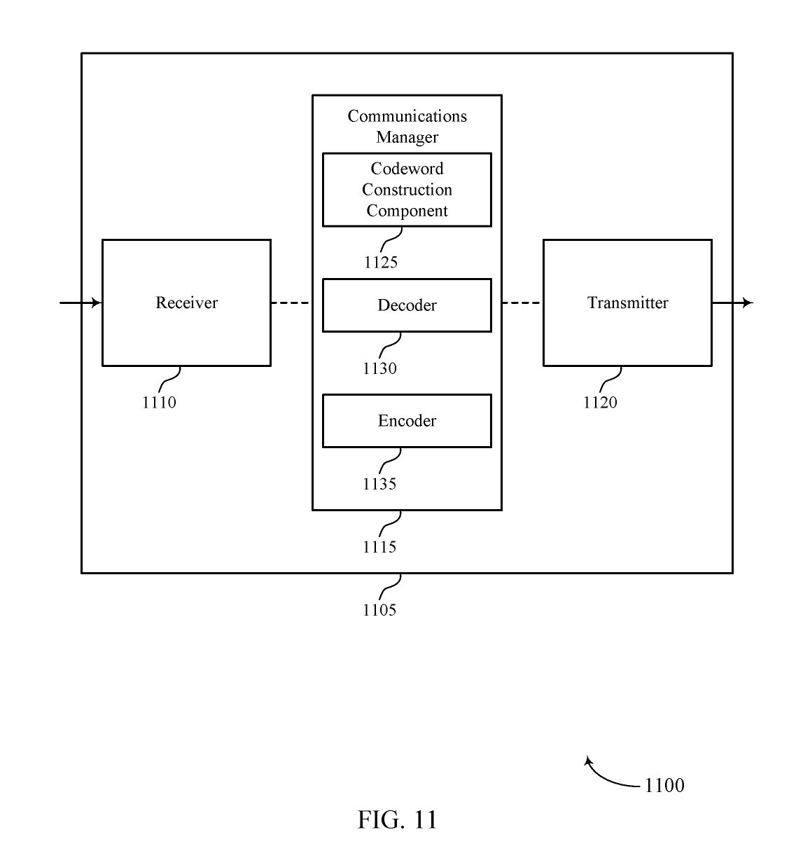

FIG. 11 shows a block diagram 1100 of a wireless device 1105 that supports nominal complexity and weighted combinations for polar code construction in accordance with aspects of the present disclosure. Wireless device 1105 may be an example of aspects of a wireless device 1005 as described with reference to FIG. 10 or a UE 115, base station 105, or device 200. Wireless device 1105 may include receiver 1110, communications manager 1115, and transmitter 1120. Wireless device 1105 may also include a processor. Each of these components may be in communication with one another (e.g., via one or more buses).

Receiver 1110 may receive information such as packets, user data, or control information associated with various information channels (e.g., control channels, data channels, and information related to nominal complexity and weighted combinations for polar code construction, etc.). Information may be passed on to other components of the device. The receiver 1110 may be an example of aspects of the transceiver 1335 described with reference to FIG. 13. The receiver 1110 may utilize a single antenna or a set of antennas.

Communications manager 1115 may be an example of aspects of the communications manager 1215 described with reference to FIG. 12. Communications manager 1115 may also include codeword construction component 1125, decoder 1130, and encoder 1135.

Codeword construction component 1125 may identify a set of polar bit channel indices corresponding to the plurality of information bits, where each polar bit channel index of the set of polar bit channel indices is selected from a plurality of polar bit channel indices of the polar code based on a reliability metric and a decoding complexity metric. In some cases, codeword construction component 1125 may adopt a modified provisional set of polar bit channel indices having a highest modified aggregate performance metric as the set of polar bit channel indices. In some cases, the decoding complexity metric is based on a number of LLR derivations, a number of bit feedback operations, or a combination thereof. In some cases, one or both of the number of bit feedback operations or the number of LLR derivations is based on a tree traversal depth between the each polar bit channel index and a prior polar bit channel index of the set of polar bit channel indices. In some cases, the decoding complexity metric is determined based on merging single parity check decoding operations and repetition decoding operations for a subtree of the polar code. In some cases, the subtree includes less than two of the set of polar bit channel indices and at least one frozen bit index. In some cases, the decoding complexity metric for the at least one polar bit channel index is generated based on a tree traversal depth between a polar bit channel index of the set of polar bit channel indices prior to the at least one polar bit channel index and the subtree.

Decoder 1130 may decode the codeword to obtain the set of information bits based on the set of polar bit channel indices. Encoder 1135 may encode the set of information bits according to the polar code based on the set of polar bit channel indices to obtain a codeword. In some cases, decoder 1130 and encoder 1135 may be the same component (e.g., an encoder/decoder 210 as described with reference to FIG. 2) or may otherwise share circuitry.

Transmitter 1120 may transmit signals generated by other components of the device. In some examples, the transmitter 1120 may be collocated with a receiver 1110 in a transceiver module. For example, the transmitter 1120 may be an example of aspects of the transceiver 1335 described with reference to FIG. 13. The transmitter 1120 may utilize a single antenna or a set of antennas.

FIG. 12 shows a block diagram 1200 of a communications manager 1215 that supports nominal complexity and weighted combinations for polar code construction in accordance with aspects of the present disclosure. The communications manager 1215 may be an example of aspects of a communications manager 1015, a communications manager 1115, or a communications manager 1215 described with reference to FIGS. 10, 11, and 12. The communications manager 1215 may include codeword construction component 1220, decoder 1225, encoder 1230, codeword test component 1235, performance component 1240, modification component 1245, and weighting component 1250. Each of these modules may communicate, directly or indirectly, with one another (e.g., via one or more buses).

Codeword construction component 1220 may identify a set of polar bit channel indices corresponding to the plurality of information bits, where each polar bit channel index of the set of polar bit channel indices is selected from a set of polar bit channel indices of the polar code based on a reliability metric and a decoding complexity metric. In some cases, codeword construction component 1220 may adopt a modified provisional set of polar bit channel indices having a highest modified aggregate performance metric as the set of polar bit channel indices. In some cases, the decoding complexity metric is based on a number of LLR derivations, a number of bit feedback operations, or a combination thereof. In some cases, one or both of the number of bit feedback operations or the number of LLR derivations is based on a tree traversal depth between the each polar bit channel index and a prior polar bit channel index of the set of polar bit channel indices. In some cases, the decoding complexity metric is determined based on merging single parity check decoding operations and repetition decoding operations for a subtree of the polar code. In some cases, the subtree includes less than two of the set of polar bit channel indices and at least one frozen bit index. In some cases, the decoding complexity metric for the at least one polar bit channel index is generated based on a tree traversal depth between a polar bit channel index of the set of polar bit channel indices prior to the at least one polar bit channel index and the subtree. Decoder 1225 may decode the codeword to obtain the set of information bits based on the set of polar bit channel indices. Encoder 1230 may encode the set of information bits according to the polar code based on the set of polar bit channel indices to obtain a codeword. In some cases, decoder 1225 and encoder 1230 may be the same component (e.g., an encoder/decoder 210 as described with reference to FIG. 2) or may otherwise share circuitry.

Codeword test component 1235 may communicate with codeword construction component 1220 to identify the set of polar bit channel indices. In some cases, codeword test component 1235 may determine a provisional set of polar bit channel indices for the set of information bits based on respective reliability metrics for the set of polar bit channel indices of the polar code. Performance component 1240 may determine an aggregate performance metric based on the combination of the respective reliability metrics and provisional decoding complexity metrics for the provisional set of polar bit channel indices.

Modification component 1245 may modify at least one index of the provisional set of polar bit channel indices. Modification component 1245 may determine a modified aggregate performance metric based on the combination of the respective reliability metrics and modified provisional decoding complexity metrics for the modified provisional set of polar bit channel indices. Modification component 1245 may iteratively perform the modifying and the determining of the modified aggregate performance metric for each of a set of search branches.

Weighting component 1250 may communicate with codeword test component 1235 to identify the set of polar bit channel indices. In some cases, a combination of the respective reliability metric and the decoding complexity metric is determined by applying a first weighting factor to the respective reliability metric and applying a second weighting factor to the decoding complexity metric. In some cases, one or both of the first weighting factor or the second weighting factor is based on a type of wireless communication protocol associated with the codeword. In some cases, the type of wireless communication protocol includes one of eMBB, URLLC, IoT, or MTC. In some cases, an aggregate reliability weight for eMBB is greater than an aggregate reliability weight for URLLC and MTC, where the aggregate reliability weights are determined based on the first weighting factor applied to the respective reliability metrics. In some cases, an aggregate complexity weight for eMBB is less than an aggregate complexity weight for URLLC and MTC, where the aggregate complexity weights are determined based on the second weighting factor applied to the decoding complexity metrics.

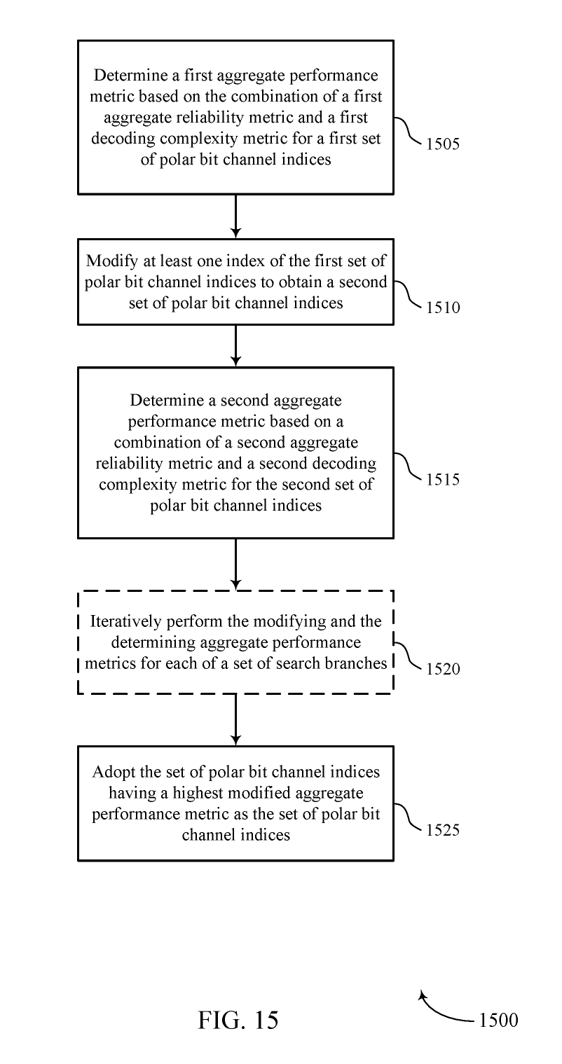

In some cases, the operations of one or more of codeword test component 1235, performance component 1240, modification component 1245, or weighting component 1250 may be performed by another device (e.g., a testing entity, a network controller, or the like), and communications manager 1215 may be configured (e.g., statically, dynamically) to operate according to results of the testing operations. For example, the testing entity may identify an optimal codeword structure for a given type of communication using techniques described herein, and communications manager 1215 may operate using the codeword structure identified by the testing entity. As an example, the testing entity may perform aspects of the operations described with reference to FIG. 15.

FIG. 13 shows a diagram of a system 1300 including a device 1305 that supports nominal complexity and weighted combinations for polar code construction in accordance with aspects of the present disclosure. Device 1305 may be an example of or include the components of wireless device 1005, wireless device 1105, or a UE 115, base station 105, or device 200 as described above, e.g., with reference to FIGS. 10 and 11. Device 1305 may include components for bi-directional voice and data communications including components for transmitting and receiving communications, including communications manager 1315, processor 1320, memory 1325, software 1330, transceiver 1335, antenna 1340, and I/O controller 1345. These components may be in electronic communication via one or more buses (e.g., bus 1310).

Processor 1320 may include an intelligent hardware device, (e.g., a general-purpose processor, a DSP, a central processing unit (CPU), a microcontroller, an ASIC, an FPGA, a programmable logic device, a discrete gate or transistor logic component, a discrete hardware component, or any combination thereof). In some cases, processor 1320 may be configured to operate a memory array using a memory controller. In other cases, a memory controller may be integrated into processor 1320. Processor 1320 may be configured to execute computer-readable instructions stored in a memory to perform various functions (e.g., functions or tasks supporting nominal complexity and weighted combinations for polar code construction).

Memory 1325 may include random access memory (RAM) and read only memory (ROM). The memory 1325 may store computer-readable, computer-executable software 1330 including instructions that, when executed, cause the processor to perform various functions described herein. In some cases, the memory 1325 may contain, among other things, a basic input/output system (BIOS) which may control basic hardware or software operation such as the interaction with peripheral components or devices.

Software 1330 may include code to implement aspects of the present disclosure, including code to support nominal complexity and weighted combinations for polar code construction. Software 1330 may be stored in a non-transitory computer-readable medium such as system memory or other memory. In some cases, the software 1330 may not be directly executable by the processor but may cause a computer (e.g., when compiled and executed) to perform functions described herein.

Transceiver 1335 may communicate bi-directionally, via one or more antennas, wired, or wireless links as described above. For example, the transceiver 1335 may represent a wireless transceiver and may communicate bi-directionally with another wireless transceiver. The transceiver 1335 may also include a modem to modulate the packets and provide the modulated packets to the antennas for transmission, and to demodulate packets received from the antennas. In some cases, the wireless device may include a single antenna 1340. However, in some cases the device may have more than one antenna 1340, which may be capable of concurrently transmitting or receiving multiple wireless transmissions.

I/O controller 1345 may manage input and output signals for device 1305. I/O controller 1345 may also manage peripherals not integrated into device 1305. In some cases, I/O controller 1345 may represent a physical connection or port to an external peripheral. In some cases, I/O controller 1345 may utilize an operating system such as iOS®, ANDROID®, MS-DOS®, MS-WINDOWS®, OS/2®, UNIX®, LINUX®, or another known operating system. In other cases, I/O controller 1345 may represent or interact with a modem, a keyboard, a mouse, a touchscreen, or a similar device. In some cases, I/O controller 1345 may be implemented as part of a processor. In some cases, a user may interact with device 1305 via I/O controller 1345 or via hardware components controlled by I/O controller 1345.

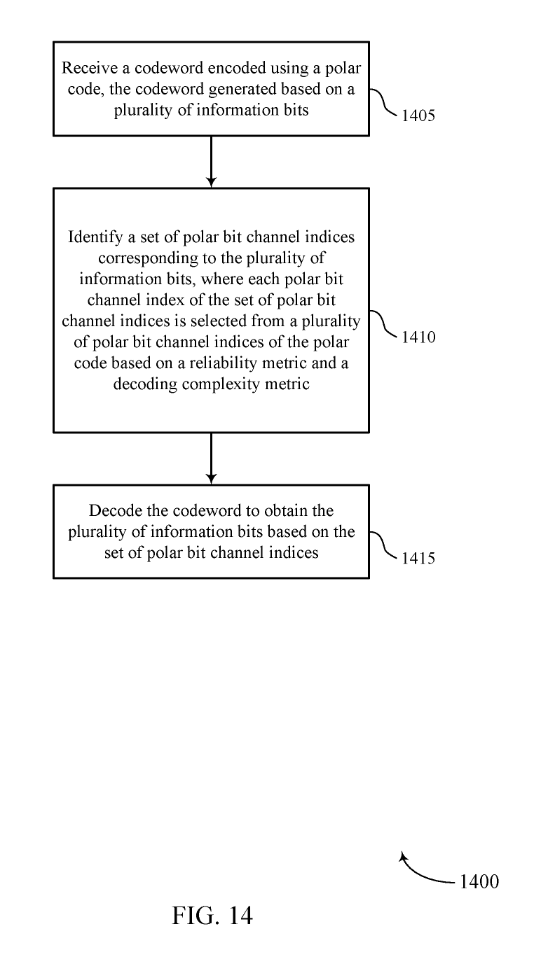

FIG. 14 shows a flowchart illustrating a method 1400 for nominal complexity and weighted combinations for polar code construction in accordance with aspects of the present disclosure. The operations of method 1400 may be implemented by a UE 115, base station 105, or device 200 or its components as described herein. For example, the operations of method 1400 may be performed by a communications manager as described with reference to FIGS. 10 through 13. In some examples, a UE 115, base station 105, or device 200 may execute a set of codes to control the functional elements of the device to perform the functions described below. Additionally or alternatively, the UE 115, base station 105, or device 200 may perform aspects of the functions described below using special-purpose hardware.

At block 1405 the UE 115, base station 105, or device 200 may receive a codeword encoded using a polar code, the codeword generated based at least in part on a plurality of information bits. The operations of block 1405 may be performed according to the methods described herein. In certain examples, aspects of the operations of block 1405 may be performed by a receiver as described with reference to FIGS. 10 through 13.

At block 1410 the UE 115, base station 105, or device 200 may identify a set of polar bit channel indices corresponding to the plurality of information bits, wherein each polar bit channel index of the set of polar bit channel indices is selected from a plurality of polar bit channel indices of the polar code based at least in part on a reliability metric and a decoding complexity metric. The operations of block 1410 may be performed according to the methods described herein. In certain examples, aspects of the operations of block 1410 may be performed by a codeword construction component as described with reference to FIGS. 10 through 13.

At block 1415 the UE 115, base station 105, or device 200 may decode the codeword to obtain the plurality of information bits based at least in part on the set of polar bit channel indices. The operations of block 1415 may be performed according to the methods described herein. In certain examples, aspects of the operations of block 1415 may be performed by a decoder as described with reference to FIGS. 10 through 13.

FIG. 15 shows a flowchart illustrating a method 1500 for nominal complexity and weighted combinations for polar code construction in accordance with aspects of the present disclosure. The operations of method 1500 may be implemented by a UE 115, base station 105, or device 200 or its components as described herein. For example, the operations of method 1500 may be performed by a communications manager as described with reference to FIGS. 10 through 13. In some examples, a UE 115, base station 105, or device 200 may execute a set of codes to control the functional elements of the device to perform the functions described below. Additionally or alternatively, the UE 115, base station 105, or device 200 may perform aspects of the functions described below using special-purpose hardware.

At block 1505 the UE 115, base station 105, or device 200 may determine a first aggregate performance metric based at least in part on a reliability metric for a first (e.g., provisional) set of polar bit channel indices, a first decoding complexity metric for the first set of polar bit channel indices, or both. The operations of block 1515 may be performed according to the methods described herein. In certain examples, aspects of the operations of block 1515 may be performed by a performance component as described with reference to FIGS. 10 through 13.

At block 1510 the UE 115, base station 105, or device 200 may modify at least one index of the first set of polar bit channel indices to obtain a second set of polar bit channel indices. The operations of block 1520 may be performed according to the methods described herein. In certain examples, aspects of the operations of block 1520 may be performed by a modification component as described with reference to FIGS. 10 through 13.

At block 1515 the UE 115, base station 105, or device 200 may determine a second aggregate performance metric based at least in part on the combination of a second aggregate reliability metric (e.g., determined from respective reliability metrics of the second set of polar bit channel indices) and a second decoding complexity metric for the second set of polar bit channel indices. The operations of block 1525 may be performed according to the methods described herein. In certain examples, aspects of the operations of block 1525 may be performed by a modification component as described with reference to FIGS. 10 through 13.

At block 1520 the UE 115, base station 105, or device 200 may perform (e.g., iteratively) the modifying and the determining of the aggregate performance metric for each of a plurality of search branches. The operations of block 1530 may be performed according to the methods described herein. In certain examples, aspects of the operations of block 1530 may be performed by a modification component as described with reference to FIGS. 10 through 13.

At block 1525 the UE 115, base station 105, or device 200 may adopt the set of polar bit channel indices having a highest aggregate performance metric as the final set of polar bit channel indices. The operations of block 1535 may be performed according to the methods described herein. In certain examples, aspects of the operations of block 1535 may be performed by a codeword construction component as described with reference to FIGS. 10 through 13.

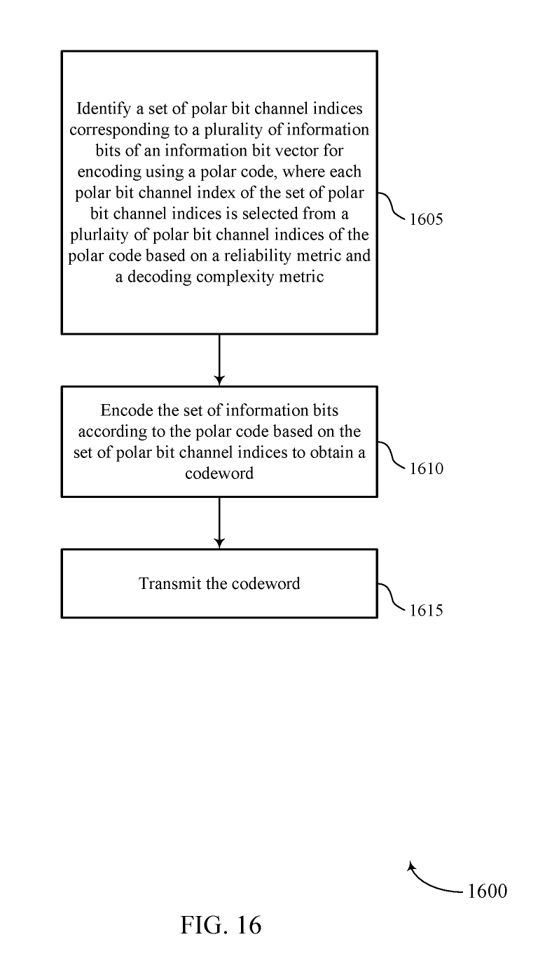

FIG. 16 shows a flowchart illustrating a method 1600 for nominal complexity and weighted combinations for polar code construction in accordance with aspects of the present disclosure. The operations of method 1600 may be implemented by a UE 115, base station 105, or device 200 or its components as described herein. For example, the operations of method 1600 may be performed by a communications manager as described with reference to FIGS. 10 through 13. In some examples, a UE 115, base station 105, or device 200 may execute a set of codes to control the functional elements of the device to perform the functions described below. Additionally or alternatively, the UE 115, base station 105, or device 200 may perform aspects of the functions described below using special-purpose hardware.

At block 1605 the UE 115, base station 105, or device 200 may identify a set of polar bit channel indices corresponding to a plurality of information bits of an information bit vector for encoding using a polar code, wherein each polar bit channel index of the set of polar bit channel indices is selected from a plurality of polar bit channel indices of the polar code based at least in part on a reliability metric and a decoding complexity metric. The operations of block 1605 may be performed according to the methods described herein. In certain examples, aspects of the operations of block 1605 may be performed by a codeword construction component as described with reference to FIGS. 10 through 13.

At block 1610 the UE 115, base station 105, or device 200 may encode the plurality of information bits according to the polar code based at least in part on the set of polar bit channel indices to obtain a codeword. The operations of block 1610 may be performed according to the methods described herein. In certain examples, aspects of the operations of block 1610 may be performed by a encoder as described with reference to FIGS. 10 through 13.

At block 1615 the UE 115, base station 105, or device 200 may transmit the codeword. The operations of block 1615 may be performed according to the methods described herein. In certain examples, aspects of the operations of block 1615 may be performed by a transmitter as described with reference to FIGS. 10 through 13.

It should be noted that the methods described above describe possible implementations, and that the operations and the steps may be rearranged or otherwise modified and that other implementations are possible. Furthermore, aspects from two or more of the methods may be combined.

Techniques described herein may be used for various wireless communications systems such as code division multiple access (CDMA), time division multiple access (TDMA), frequency division multiple access (FDMA), orthogonal frequency division multiple access (OFDMA), single carrier frequency division multiple access (SC-FDMA), and other systems. The terms “system” and “network” are often used interchangeably. A code division multiple access (CDMA) system may implement a radio technology such as CDMA2000, Universal Terrestrial Radio Access (UTRA), etc. CDMA2000 covers IS-2000, IS-95, and IS-856 standards. IS-2000 Releases may be commonly referred to as CDMA2000 1×, 1×, etc. IS-856 (TIA-856) is commonly referred to as CDMA2000 1×EV-DO, High Rate Packet Data (HRPD), etc. UTRA includes Wideband CDMA (WCDMA) and other variants of CDMA. A TDMA system may implement a radio technology such as Global System for Mobile Communications (GSM).

An OFDMA system may implement a radio technology such as Ultra Mobile Broadband (UMB), Evolved UTRA (E-UTRA), Institute of Electrical and Electronics Engineers (IEEE) 802.11 (Wi-Fi), IEEE 802.16 (WiMAX), IEEE 802.20, Flash-OFDM, etc. UTRA and E-UTRA are part of Universal Mobile Telecommunications System (UMTS). LTE and LTE-A are releases of UMTS that use E-UTRA. UTRA, E-UTRA, UMTS, LTE, LTE-A, NR, and GSM are described in documents from the organization named “3rd Generation Partnership Project” (3GPP). CDMA2000 and UMB are described in documents from an organization named “3rd Generation Partnership Project 2” (3GPP2). The techniques described herein may be used for the systems and radio technologies mentioned above as well as other systems and radio technologies. While aspects of an LTE or an NR system may be described for purposes of example, and LTE or NR terminology may be used in much of the description, the techniques described herein are applicable beyond LTE or NR applications.

In LTE/LTE-A networks, including such networks described herein, the term evolved node B (eNB) may be generally used to describe the base stations. The wireless communications system or systems described herein may include a heterogeneous LTE/LTE-A or NR network in which different types of eNBs provide coverage for various geographical regions. For example, each eNB, next generation NodeB (gNB), or base station may provide communication coverage for a macro cell, a small cell, or other types of cell. The term “cell” may be used to describe a base station, a carrier or component carrier associated with a base station, or a coverage area (e.g., sector, etc.) of a carrier or base station, depending on context.

Base stations may include or may be referred to by those skilled in the art as a base transceiver station, a radio base station, an access point, a radio transceiver, a NodeB, eNodeB (eNB), gNB, Home NodeB, a Home eNodeB, or some other suitable terminology. The geographic coverage area for a base station may be divided into sectors making up only a portion of the coverage area. The wireless communications system or systems described herein may include base stations of different types (e.g., macro or small cell base stations). The UEs described herein may be able to communicate with various types of base stations and network equipment including macro eNBs, small cell eNBs, gNBs, relay base stations, and the like. There may be overlapping geographic coverage areas for different technologies.

A macro cell generally covers a relatively large geographic area (e.g., several kilometers in radius) and may allow unrestricted access by UEs with service subscriptions with the network provider. A small cell is a lower-powered base station, as compared with a macro cell, that may operate in the same or different (e.g., licensed, unlicensed, etc.) frequency bands as macro cells. Small cells may include pico cells, femto cells, and micro cells according to various examples. A pico cell, for example, may cover a small geographic area and may allow unrestricted access by UEs with service subscriptions with the network provider. A femto cell may also cover a small geographic area (e.g., a home) and may provide restricted access by UEs having an association with the femto cell (e.g., UEs in a closed subscriber group (CSG), UEs for users in the home, and the like). An eNB for a macro cell may be referred to as a macro eNB. An eNB for a small cell may be referred to as a small cell eNB, a pico eNB, a femto eNB, or a home eNB. An eNB may support one or multiple (e.g., two, three, four, and the like) cells (e.g., component carriers).

The wireless communications system or systems described herein may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. The techniques described herein may be used for either synchronous or asynchronous operations.

The downlink transmissions described herein may also be called forward link transmissions while the uplink transmissions may also be called reverse link transmissions. Each communication link described herein—including, for example, wireless communications system 100 and 200 of FIGS. 1 and 2—may include one or more carriers, where each carrier may be a signal made up of multiple sub-carriers (e.g., waveform signals of different frequencies).

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media may comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method for wireless communication, comprising:
receiving a codeword encoded using a polar code, the codeword generated based at least in part on a plurality of information bits;
identifying a set of polar bit channel indices corresponding to the plurality of information bits, wherein the set of polar bit channel indices is selected from a plurality of polar bit channel indices of the polar code based at least in part on reliability metrics and a decoding complexity metric associated with the set of polar bit channel indices; and
decoding the codeword to obtain the plurality of information bits based at least in part on the set of polar bit channel indices.

2. The method of claim 1, wherein the decoding complexity metric is based at least in part on a number of logarithmic likelihood ratio (LLR) derivations for at least one polar bit channel index of the set of polar bit channel indices, a number of bit feedback operations for the at least one polar bit channel index of the set of polar bit channel indices, or a combination thereof.

3. The method of claim 2, wherein, for the at least one polar bit channel index of the set of polar bit channel indices, one or both of the number of bit feedback operations or the number of LLR derivations is based at least in part on a tree traversal depth between the at least one polar bit channel index and a prior polar bit channel index of the set of polar bit channel indices.

4. The method of claim 1, wherein the decoding complexity metric is determined based at least in part on merging single parity check decoding operations and repetition decoding operations for a subtree of the polar code.

5. The method of claim 4, wherein the subtree comprises less than two of the set of polar bit channel indices and at least one frozen bit index.

6. The method of claim 4, wherein the decoding complexity metric is generated based at least in part on a tree traversal depth between adjacent polar bit channel indices of the set of polar bit channel indices, the subtree comprising one of the adjacent polar bit channel indices.

7. The method of claim 1, wherein the identifying the set of polar bit channel indices comprises:
determining a first aggregate performance metric for a first set of polar bit channel indices, the first aggregate performance metric based at least in part on a first decoding complexity metric and a first aggregate reliability metric for the first set of polar bit channel indices;
modifying at least one index of the first set of polar bit channel indices to obtain a second set of polar bit channel indices;
determining a second aggregate performance metric for the second set of polar bit channel indices based at least in part on a second decoding complexity metric and a second aggregate reliability metric for the second set of polar bit channel indices; and
adopting the second set of polar bit channel indices based at least in part on a comparison of the first aggregate performance metric with the second aggregate performance metric.

8. The method of claim 1, further comprising:
determining, for each of the plurality of polar bit channel indices, a weighted combination of a respective reliability metric and a respective decoding complexity metric by applying a first weighting factor to the respective reliability metric and applying a second weighting factor to the respective decoding complexity metric, wherein the set of polar bit channel indices is selected from the plurality of polar bit channel indices of the polar code based at least in part on the weighted combination.

9. The method of claim 8, wherein one or both of the first weighting factor or the second weighting factor is based at least in part on a type of wireless communication protocol associated with the codeword.

10. The method of claim 9, wherein the type of wireless communication protocol comprises one of enhanced mobile broadband (eMBB), ultra-reliable low latency communication (URLLC), Internet of Things (IoT) communication, or machine type communication (MTC).

11. The method of claim 10, wherein an aggregate reliability weight for eMBB is greater than an aggregate reliability weight for URLLC and MTC, wherein the aggregate reliability weights are determined based at least in part on the first weighting factor applied to the reliability metric.

12. The method of claim 10, wherein an aggregate complexity weight for eMBB is less than an aggregate complexity weight for URLLC and MTC, wherein the aggregate complexity weights are determined based at least in part on the second weighting factor applied to the decoding complexity metric.

13. A method for wireless communication, comprising:
identifying a set of polar bit channel indices corresponding to a plurality of information bits of an information bit vector for encoding using a polar code, wherein the set of polar bit channel indices is selected from a plurality of polar bit channel indices of the polar code based at least in part on reliability metrics and a decoding complexity metric associated with the set of polar bit channel indices;
encoding the plurality of information bits according to the polar code based at least in part on the set of polar bit channel indices to obtain a codeword; and
transmitting the codeword.

14. The method of claim 13, wherein the decoding complexity metric is based at least in part on a number of logarithmic likelihood ratio (LLR) derivations for at least one polar bit channel index of the set of polar bit channel indices, a number of bit feedback operations for the at least one polar bit channel index of the set of polar bit channel indices, or a combination thereof.

15. The method of claim 14, wherein, for the at least one polar bit channel index of the set of polar bit channel indices, one or both of the number of bit feedback operations or the number of LLR derivations is based at least in part on a tree traversal depth between the at least one polar bit channel index and a prior polar bit channel index of the set of polar bit channel indices.

16. The method of claim 13, wherein the decoding complexity metric is determined based at least in part on merging single parity check decoding operations and repetition decoding operations for a subtree of the polar code.

17. The method of claim 16, wherein the subtree comprises less than two of the set of polar bit channel indices and at least one frozen bit index.

18. The method of claim 16, wherein the decoding complexity metric is generated based at least in part on a tree traversal depth between adjacent polar bit channel indices of the set of polar bit channel indices, the subtree comprising one of the adjacent polar bit channel indices.

19. The method of claim 13, wherein the identifying the set of polar bit channel indices comprises:
determining a first aggregate performance metric for a first set of polar bit channel indices, the first aggregate performance metric based at least in part on a first decoding complexity metric and an aggregate reliability metric for the first set of polar bit channel indices;
modifying at least one index of the first set of polar bit channel indices to obtain a second set of polar bit channel indices;
determining a second aggregate performance metric for the second set of polar bit channel indices based at least in part on a second decoding complexity metric for the second set of polar bit channel indices and the aggregate reliability metric; and
adopting the second set of polar bit channel indices based at least in part on a comparison of the first aggregate performance metric with the second aggregate performance metric.

20. The method of claim 13, further comprising:
determining, for each of the plurality of polar bit channel indices, a weighted combination of a respective reliability metric and a respective decoding complexity metric by applying a first weighting factor to the respective reliability metric and applying a second weighting factor to the respective decoding complexity metric, wherein the set of polar bit channel indices is selected from the plurality of polar bit channel indices of the polar code based at least in part on the weighted combination.

21. The method of claim 20, wherein one or both of the first weighting factor or the second weighting factor is based at least in part on a type of wireless communication protocol associated with the codeword.

22. The method of claim 21, wherein the type of wireless communication protocol comprises one of enhanced mobile broadband (eMBB), ultra-reliable low latency communication (URLLC), Internet of Things (IoT) communication, or machine type communication (MTC).

23. The method of claim 22, wherein an aggregate reliability weight for eMBB is greater than an aggregate reliability weight for URLLC and MTC, wherein the aggregate reliability weights are determined based at least in part on the first weighting factor applied to the reliability metric.

24. The method of claim 22, wherein an aggregate complexity weight for eMBB is less than an aggregate complexity weight for URLLC and MTC, wherein the aggregate complexity weights are determined based at least in part on the second weighting factor applied to the decoding complexity metric.

25. An apparatus for wireless communication, comprising:
a processor;
memory in electronic communication with the processor; and
instructions stored in the memory and operable, when executed by the processor, to cause the apparatus to:
receive a codeword encoded using a polar code, the codeword generated based at least in part on a plurality of information bits;
identify a set of polar bit channel indices corresponding to the plurality of information bits, wherein the set of polar bit channel indices is selected from a plurality of polar bit channel indices of the polar code based at least in part on a reliability metric and a decoding complexity metric associated with the set of polar bit channel indices; and
decode the codeword to obtain the plurality of information bits based at least in part on the set of polar bit channel indices.

26. The apparatus of claim 25, wherein the decoding complexity metric is based at least in part on a number of logarithmic likelihood ratio (LLR) derivations for at least one polar bit channel index of the set of polar bit channel indices, a number of bit feedback operations for the at least one polar bit channel index of the set of polar bit channel indices, or a combination thereof.

27. The apparatus of claim 25, wherein the decoding complexity metric is determined based at least in part on merging single parity check decoding operations and repetition decoding operations for a subtree of the polar code.

28. An apparatus for wireless communication, comprising:
a processor;
memory in electronic communication with the processor; and
instructions stored in the memory and operable, when executed by the processor, to cause the apparatus to:
identify a set of polar bit channel indices corresponding to a plurality of information bits, wherein the set of polar bit channel indices is selected from a plurality of polar bit channel indices of a polar code based at least in part on a reliability metric and a decoding complexity metric associated with the set of polar bit channel indices;
encode the plurality of information bits according to the polar code based at least in part on the set of polar bit channel indices to obtain a codeword; and
transmit the codeword.

29. The apparatus of claim 28, wherein the decoding complexity metric is based at least in part on a number of logarithmic likelihood ratio (LLR) derivations for at least one polar bit channel index of the set of polar bit channel indices, a number of bit feedback operations for the at least one polar bit channel index of the set of polar bit channel indices, or a combination thereof.

30. The apparatus of claim 28, wherein the decoding complexity metric is determined based at least in part on merging single parity check decoding operations and repetition decoding operations for a subtree of the polar code.
